(19) United States
(12) Patent Application Publication
(10) Pub. No.: US 2024/0404951 A1
(43) Pub. Date: Dec. 5, 2024

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Chia-Che CHUNG, Hsinchu City (TW); Chia-Jung TSEN, Taoyuan City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/327,848

(22) Filed: Jun. 1, 2023

(51) Int. Cl. H01L 23/528; H01L 21/768; H01L 23/48; H01L 23/522; H01L 29/40

(52) U.S. Cl. CPC H01L 23/5286; H01L 21/76898; H01L 23/481; H01L 23/5226; H01L 29/401

(57) ABSTRACT

A method includes forming a semiconductor device over a front-side of a substrate, the semiconductor device comprising a channel region, a gate structure across the channel region, and source/drain regions on the channel region and at opposite sides of the gate structure; forming a first source/drain contact on a first one of the source/drain regions; forming a front-side interconnect structure over the first source/drain contact; forming a first dielectric through-silicon via extending through the substrate from a cross-sectional view, the first dielectric through-silicon via overlapping the first source/drain contact from a top view; forming a back-side interconnect structure over a back-side of the substrate, wherein the first dielectric through-silicon via has a back-side surface in contact with the back-side interconnect structure.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic cross-sectional view of a semiconductor structure in accordance with some embodiments of the present disclosure.

FIG. 1B illustrates a schematic top view of a semiconductor structure corresponding to a region in FIG. 1A.

FIGS. 1C and 1D illustrate schematic top views of semiconductor structures corresponding to FIG. 1B according to some embodiments of the present disclosure.

FIGS. 1E, 1F, and 1G illustrate schematic cross-sectional views corresponding to a cross-sectional view obtained from FIG. 1A according to some embodiments of the present disclosure.

FIGS. 2 and 3 illustrate schematic cross-sectional views of semiconductor structures in accordance with some embodiments of the present disclosure.

FIGS. 4A-4K, 4M, and 40 illustrate cross-sectional views of intermediate stages in the formation of a semiconductor structure in accordance with some embodiments.

FIGS. 4L, 4N, and 4P illustrate schematic cross-sectional views of a semiconductor structure corresponding to FIGS. 4K, 4M, and 40, respectively, according to some embodiments of the present disclosure.

FIGS. 4Q-4T illustrate schematic cross-sectional views of different semiconductor structures corresponding to FIG. 4O according to some embodiments of the present disclosure.

FIGS. 5A-5I, 5K, and 5M illustrate cross-sectional views of intermediate stages in the formation of a semiconductor structure in accordance with some embodiments.

FIGS. 5J, 5L, and 5N illustrate schematic cross-sectional views of a semiconductor structure corresponding to FIGS. 5I, 5K, and 5M, respectively, according to some embodiments of the present disclosure.

FIGS. 5O-5T illustrate schematic cross-sectional views of different semiconductor structures corresponding to FIG. 5I according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present disclosure are directed to, but not otherwise limited to, a fin-like field-effect transistor (FinFET) device. The FinFET device, for example, may be a complementary metal-oxide-semiconductor (CMOS) device including a P-type metal-oxide-semiconductor (PMOS) FinFET device and an N-type metal-oxide-semiconductor (NMOS) FinFET device. The following disclosure will continue with one or more FinFET examples to illustrate various embodiments of the present disclosure. It is understood, however, that the application should not be limited to a particular type of device, except as specifically claimed.

The fins may be patterned by any suitable method. For example, the fins may be patterned using one or more photolithography processes, including double-patterning or multi-patterning processes. The double-patterning or the multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in high heat density and poor thermal dissipation performance thereof. Increased heat density in IC structure can lead to electromigration and reliability issues. Thus, nano through-silicon vias (nTSVs) connecting wafer front-side to wafer back-side to form wafer back-side routing or dummy thermal TSVs in 3D packaging can be provided to improve heat dissipation in the IC structure. Nevertheless, the metal inside nTSV and dummy thermal TSV will lead to parasitic capacitance and/or induce leakage path, wherein in turn impacts the performance of the IC structure.

Therefore, the present disclosure in various embodiments provides a TSV that is made of a dielectric material having a higher thermal conductivity than the substrate to improve heat dissipation of the IC structure. The TSV can be metal-free. The dielectric TSV may be used to act as a heat sink for the IC structure to discharge the heat generated by the semiconductor device from a circuit local hotspot to outside of the IC structure. In some embodiments, the thermal conductivity of the dielectric TSV may be greater than about 150 W/m/K (kₜₕ). Because the dielectric TSV can be metal-free, no parasitic capacitance will be generated in the IC structure around the dielectric TSV, which in turn prevents an additional leakage path in the IC structure, and thus the performance of the IC structure can be improved.

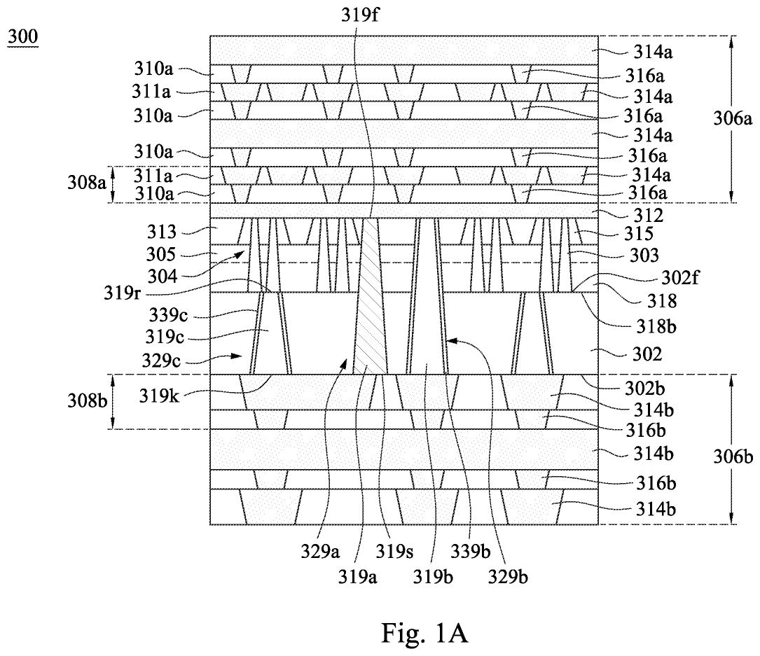

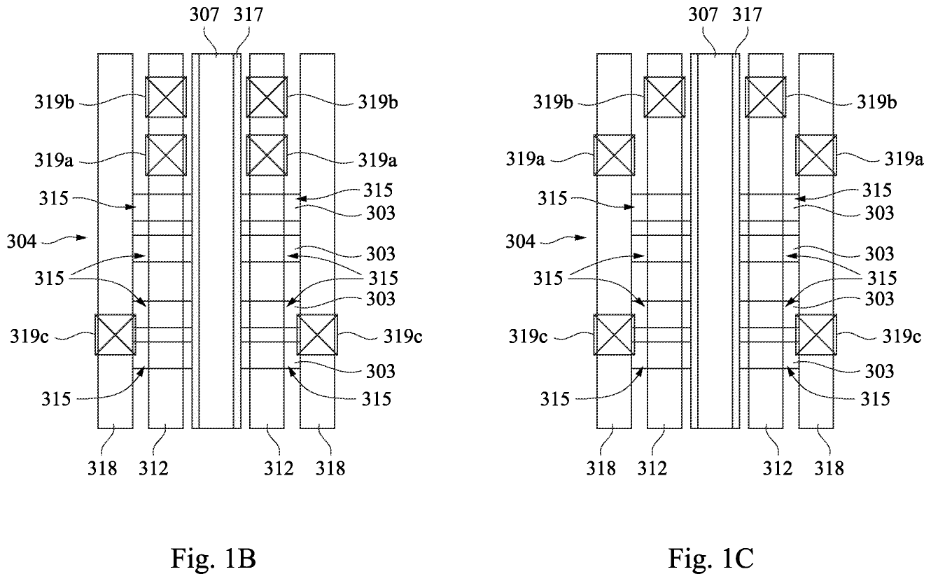

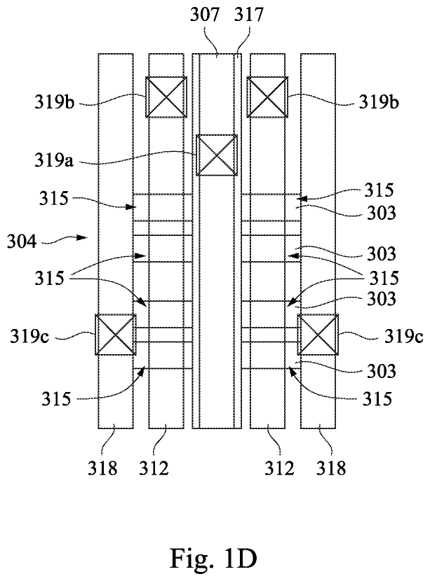

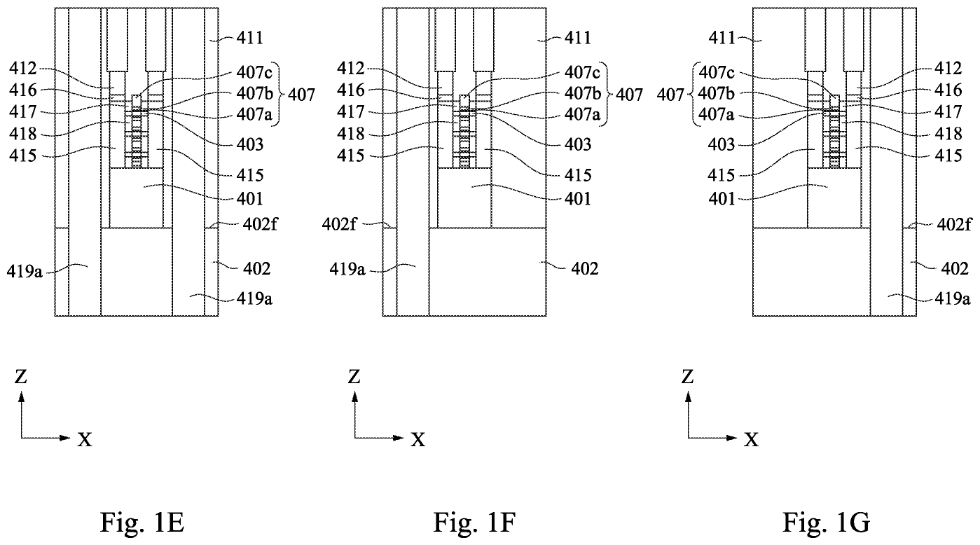

Reference is made to FIGS. 1A and 1B. FIG. 1A illustrates a schematic cross-sectional view of a semiconductor structure in accordance with some embodiments of the present disclosure. FIG. 1B illustrates a schematic top view of a semiconductor structure corresponding to a region in FIG. 1A. In some embodiments, the semiconductor structure 300 may comprise a substrate 302 as illustrated in FIG. 1A. The substrate 302 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the substrate 302 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, one or more active and/or passive devices (e.g., semiconductor device 304) are formed on a front-side 302f of the substrate 302 as illustrated in FIG. 1A. The one or more active and/or passive devices may include various N-type metal-oxide semiconductor (NMOS) and/or P-type metal-oxide semiconductor (PMOS) devices, such as transistors, capacitors, resistors, diodes, photo-diodes, fuses, and the like. One of ordinary skill in the art will appreciate that the above examples are provided for the purpose of illustration only and are not meant to limit the present disclosure in any manner. Other circuitry may be also formed as appropriate for a given application. In the depicted embodiments, the semiconductor devices 304 are fin field-effect transistors (FinFET) that are three-dimensional MOSFET structure formed in fin-like strips of semiconductor protrusions referred to as fins 303. The cross-section shown in FIG. 1A is taken along a direction perpendicular to a longitudinal axis of the fin. In some embodiments, the fin 303 can be interchangeably referred to as a channel region, a channel pattern, a fin structure, a fin pattern, or a semiconductor strip. The fin 303 may be formed by patterning the substrate 302 using photolithography and etching techniques from the front-side of the substrate 302. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 303 by etching a trench into the substrate 302 using, for example, reactive ion etching (RIE). In some embodiments, the substrate 302 may comprise any number of fins. In some other embodiments, the semiconductor devices 304 can be planar transistors or gate-all-around (GAA) transistors.

In some embodiments, shallow trench isolation (STI) regions 305 formed on opposing sidewalls of the fin 303 and buried power rails 318 formed in the STI regions 305 are illustrated in FIGS. 1A and 1B. STI regions 305 may be formed by depositing one or more dielectric materials (e.g., silicon oxide) to completely fill the trenches around the fins and then recessing the top surface of the dielectric materials. The dielectric materials of the STI regions 305 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 305 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 305 such that an upper portion of fins 303 protrudes from surrounding insulating STI regions 305. In some cases, the patterned hard mask used to form the fins 303 may also be removed by the planarization process. In some embodiments, the buried power rail 318 may be form by forming a trench extending through the STI region 305 into the substrate 302 from the front-side 302f of the substrate 302. Subsequently, a conductive material is filled in the trench to form the buried power rail 318. The conductive material may include metal, such as tungsten (W), ruthenium (Ru), aluminum (Al), copper (Cu), or other suitable conductive material. In some embodiments, the conductive material 170 may be deposited by CVD, physical vapor deposition (PVD), sputter deposition, or other techniques suitable for depositing conductive materials.

In some embodiments, a gate structure 307 (see FIG. 1B) of the semiconductor device 304 illustrated in FIGS. 1A and 1B is a high-k, metal gate (HKMG) gate structure that may be formed using a gate-last process flow. In a gate-last process flow a sacrificial dummy gate structure (not shown) is formed after forming the STI regions 305. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 305. As described in greater detail below, the dummy gate structure may be replaced by the gate structure 307 as illustrated in FIGS. 1A and 1B. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof. In some embodiments, the gate structure 307 can be interchangeably referred to as a gate, a functional gate, a gate strip, a gate pattern, or a gate layer.

Spacers 317 as illustrated in FIG. 1B are formed, for example, self-aligned to the dummy gate structures. As shown in FIG. 1B, the spacers 317 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structure leaving the spacers 317 along the sidewalls of the dummy gate structure extending laterally onto a portion of the surface of the fin 303.

Source/drain regions 315 of the semiconductor device 304 as illustrated in FIG. 1A are formed. As shown in FIG. 1A, the source/drain regions 315 are semiconductor regions in direct contact with the semiconductor fin 303. In some embodiments, the source/drain regions 315 may comprise heavily-doped regions and relatively lightly-doped drain extensions, or LDD regions. Generally, the heavily-doped regions are spaced away from the dummy gate structure using the spacers 317, whereas the LDD regions may be formed prior to forming spacers 317 and, hence, extend under the spacers 317 and, in some embodiments, extend further into a portion of the semiconductor fin 303 below the dummy gate structure. The LDD regions may be formed, for example, by implanting dopants (e.g., As, P, B, In, or the like) using an ion implantation process. The source/drain regions 315 may comprise an epitaxially grown region. For example, after forming the LDD regions, the spacers 317 may be formed and, subsequently, the heavily-doped source and drain regions may be formed self-aligned to the spacers 317 by first etching the fins to form recesses, and then depositing a crystalline semiconductor material in the recess by a selective epitaxial growth (SEG) process that may fill the recess and may extend further beyond the original surface of the fin 303 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 3014 cm⁻² to 3016 cm⁻²) of dopants may be introduced into the heavily-doped source and drain regions 315 either in situ during SEG, or by an ion implantation process performed after the SEG, or by a combination thereof. In some embodiments, the source/drain region 315 can be interchangeably referred to as a source/drain structure, a source/drain pattern, an epitaxial structure, or an epitaxial pattern. In a semiconductor device such as a transistor, the “source” and “drain” can be referred to two terminals or regions that carry charge carriers (either electrons or holes) into and out of the device. The source is the part of the transistor where the charge carriers come from. In an N-type transistor, the charge carriers are electrons, and in a P-type transistor, the charge carriers are holes. The drain is where the charge carriers go to. The gate is the control terminal for the transistor. By applying a voltage to the gate, the flow of charge carriers from the source to the drain can be controlled. Therefore, the term, “source/drain,” in a semiconductor device refers to the regions where charge carriers are injected (e.g., source) and collected (e.g., drain) for the flow of current controlled by the gate voltage.

Once the source/drain regions 315 are formed, an ILD layer 313 is deposited over the source/drain regions 315. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the ILD layer 313. The gate structure 307, illustrated in FIG. 1B, may then be formed by first removing the dummy gate structure using one or more etching techniques, thereby creating recesses between respective spacers 317. Next, a replacement gate dielectric layer comprising one more dielectrics, followed by a replacement gate metal layer comprising one or more metals, are deposited to completely fill the recesses. Excess portions of the gate structure layers may be removed from over the top surface of the ILD layer 313 using, for example, a CMP process. The resulting structure, as illustrated in FIG. 1B, may include remaining portions of the HKMG gate layers inlaid between respective spacers 317. In some embodiments, the insulating materials to form the ILD layer 313 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the ILD layer 313 may be deposited using any suitable method, such as CVD, physical vapor deposition (PVD), ALD, PEALD, PECVD, SACVD, FCVD, spin-on, and/or the like, or a combination thereof.

The gate dielectric layer includes, for example, a high-k dielectric material such as oxides and/or silicates of metals (e.g., oxides and/or silicates of Hf, Al, Zr, La, Mg. Ba, Ti, and other metals), silicon nitride, silicon oxide, and the like, or combinations thereof, or multilayers thereof. In some embodiments, the gate metal layer 304_{GM} may be a multilayered metal gate stack comprising a barrier layer, a work function layer, and a gate-fill layer formed successively on top of gate dielectric layer. Example materials for a barrier layer include TIN, TaN, Ti, Ta, or the like, or a multilayered combination thereof. A work function layer may include TIN, TaN, Ru, Mo, Al, for a p-type FET, and Ti, Ag·TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

In some embodiments, contacts 312 are formed to electrically couple the overlying front-side interconnect structure 306a to the underlying semiconductor device devices 304 through the source/drain regions 315 as illustrated in FIGS. 1A and 1B. As illustrated in FIG. 1A, the semiconductor devices 304 can be electrically connected to conductive lines 314a and the conductive vias 316a using contacts 312 formed through the intervening dielectric layers. In the example illustrated in FIG. 1A, the contacts 312 make electrical connections to the source/drain regions 315 of the semiconductor device 304. The contacts 312 may be formed using photolithography, etching and deposition techniques. For example, a patterned mask may be formed over the ILD layer 313 and used to etch openings that extend through the ILD layer 313 to expose the gate structure 307 as well as the source/drain regions 315. Thereafter, conductive liner may be formed in the openings in the ILD layer 313. Subsequently, the openings are filled with a conductive fill material. The liner comprises barrier metals used to reduce out-diffusion of conductive materials from the contacts 312 into the surrounding dielectric materials. In some embodiments, the liner may comprise two barrier metal layers. The first barrier metal comes in contact with the semiconductor material in the source/drain regions 315 and may be subsequently chemically reacted with the heavily-doped semiconductor in the source/drain regions 315 to form a low resistance ohmic contact, after which the unreacted metal may be removed. For example, if the heavily-doped semiconductor in the source/drain regions 315 is silicon or silicon-germanium alloy semiconductor, the first barrier metal may comprise Ti, Ni. Pt, Co, other suitable metals, or their alloys, and may form silicide with the source/drain regions 315. The second barrier metal layer of the conductive liner may additionally include other metals (e.g., TiN, TaN, Ta, or other suitable metals, or their alloys). A conductive fill material (e.g., W. Al, Cu, Ru, Ni, Co, alloys of these, combinations thereof, and the like) may be deposited over the conductive liner layer to fill the contact openings, using any acceptable deposition technique (e.g., CVD. ALD, PEALD, PECVD, PVD, ECP, electroless plating, or the like, or any combination thereof). Next, a planarization process (e.g., CMP) may be used to remove excess portions of all the conductive materials from over the surface of the ILD 313. The resulting conductive layer extend into the ILD layer 313 and constitute contacts 312 making physical and electrical connections to the electrodes of electronic devices, such as the semiconductor device 304 illustrated in FIG. 1A. In some embodiments, the contact 312 can be interchangeably referred to as a source/drain contact or a source/drain plug.

After forming the contacts 312, the front-side interconnect structure 306a including multiple interconnect levels may be formed, stacked vertically above the contact layers 312, in accordance with a back end of line (BEOL) scheme adopted for the integrated circuit design. In the BEOL scheme illustrated in FIG. 1A, various interconnect levels have similar features. However, it is understood that other embodiments may utilize alternate integration schemes wherein the various interconnect levels may use different features. For example, the contacts 312, which are shown as vertical connectors, may be extended to form conductive lines which transport current laterally. In some embodiments, the front-side interconnect structure 306a electrically interconnects the one or more active and/or passive devices to form functional electrical circuits within the semiconductor structure 300. The front-side interconnect structure 306a may comprise one or more metallization layers 308a. In some embodiments, the number of the metallization layers may vary according to design specifications of the semiconductor structure 300. The metallization layers 308a comprise dielectric layers 310a and 311a, respectively. The dielectric layers 311 are formed over the corresponding dielectric layers 310a. The metallization layers 308a comprise one or more horizontal interconnects, such as conductive lines 314a, respectively extending horizontally or laterally in dielectric layers 311 and vertical interconnects, such as conductive vias 316a, respectively extending vertically in dielectric layers 310a. The conductive lines 314a and the conductive vias 316a may be formed using any suitable method, such as a single damascene process, a dual damascene process, or the like. In some embodiments, the dielectric layers 310a and 311a may include low-k dielectric materials having k values, for example, lower than about 4.0 or even 2.0 disposed between such conductive features. In some embodiments, the dielectric layers may be made of, for example, phosphosilicate glass (PSG), borophosphosilicate glass (BPSG), fluorosilicate glass (FSG), SiOxCy, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The conductive lines 314a and the conductive vias 316a may comprise conductive materials such as copper, aluminum, tungsten, combinations thereof, or the like. In some embodiments, the conductive lines 314a, and the conductive vias 316a may further comprise one or more barrier/adhesion layers (not shown) to protect the respective dielectric layers 310a and 311a from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD. ALD, or the like. Formation of the front-side interconnect structure 306a can be referred to as a back-end-of-line (BEOL) process. In some embodiments, the front-side interconnect structure 306a can be interchangeably referred to as a BEOL structure or a front-side interconnect structure. Formation of the structure prior to the front-side interconnect structure 306a can be referred to as a front-end-of-line (FEOL) process. In some embodiments, the formation of the structure prior to the front-side interconnect structure 306a can be interchangeably referred to as a FEOL structure. After formation of the front-side interconnect structure 306a, the substrate 302 may be thinned from the front-side of the substrate 302 using grinding and/or wet or dry etching techniques by way of example but not limitation. In some embodiments, the substrate 302 can be interchangeably referred to as a thinned substrate.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in high heat density and poor thermal dissipation performance thereof. Increased heat density in IC structure can lead to electromigration and reliability issues. Thus, nano through-silicon vias (nTSVs) connecting wafer front-side to wafer back-side to form wafer back-side routing or dummy thermal TSVs in 3D packaging can be provided to improve heat dissipation in the IC structure. Nevertheless, the metal inside nTSV and dummy thermal TSV will lead to parasitic capacitance and/or induce leakage path, wherein in turn impacts the performance of the IC structure.

Therefore, the present disclosure in various embodiments provides a TSV 319a that is made of a dielectric material having a higher thermal conductivity than the substrate 302 (see FIG. 1A) to improve heat dissipation of the semiconductor structure 300. The TSV 319a can be metal-free. That is, the dielectric TSV 319a may be used to act as a heat sink for the semiconductor structure 300 to discharge the heat generated by the semiconductor device from a circuit local hotspot to outside of the semiconductor structure 300. In some embodiments, the thermal conductivity of the dielectric TSV 319a may be greater than about 150 W/m/K (kₜₕ). Because the dielectric TSV 319a can be metal-free, no parasitic capacitance will be generated in the semiconductor structure 300 around the dielectric TSV 319a, which in turn prevents an additional leakage path in the semiconductor structure 300, and thus the performance of the semiconductor structure 300 can be improved. In some embodiments, the dielectric TSV 319a can also be applied in three dimension (3D) packaging as a dummy thermal TSV.

As shown in FIG. 1A, the dielectric TSV 319a is formed through the substrate 302, the STI region 305, and the ILD layer 313 and in contact with the contact 312. The dielectric TSV 319a may be used act as a thermal path to relieve the thermal in the circuits. In some embodiments, the dielectric TSV 319a can be interchangeably referred to as a thermal nano TSV (thermal nTSV). Specifically, the formation of the dielectric TSV 319a is to form a TSV opening 329a passing through the substrate 302, STI region 305, and ILD layer 313 until reaching the contact 312 that is connected to signal, power, or ground. In defining the TSV opening 329a, a hard mask layer (not shown) may be formed over a back-side surface 302b of the substrate 302 followed by forming a patterned photoresist layer (not shown) thereon. The hard mask layer may be a silicon nitride layer, a silicon oxynitride layer or the like by way of example but not limitation. The photoresist layer is patterned by exposure, bake, developing, and/or other photolithography processes to provide an opening exposing the hard mask layer. The exposed hard mask layer is then etched, by a wet etch or dry etch process, using the patterned photoresist layer as a masking element to provide an opening. Using the hard mask layer and the patterned photoresist layer as mask elements, an etching process is performed to etch the exposed substrate 302, STI region 305, and ILD layer 313, and form the TSV opening 329a passing through the substrate 302, the STI region 305, and the ILD layer 313. The contact 312 may also act as an etch stop layer for etching the substrate 302 until the contact 312 is exposed. In some embodiments, the TSV opening 329a may be formed by performing any suitable etching process including, for example, a plasma etch, a chemical wet etch, a laser drill, and/or other processes. In some embodiments, the etching process includes a deep reactive ion etching (RIE) process to etch the substrate 302 from the backside surface 302b of the substrate 302.

Subsequently, the dielectric TSV 319a is formed in the TSV opening 329a and having a front-side surface 319f in contact with the contact 312 to connect to the signal, power, or ground. Specifically, a dielectric material is deposited over the substrate 302 from the back-side 302b of the substrate 302 and fills in the TSV opening 329a. In some embodiments, the dielectric material may have a thermal conductivity greater than about 150 W/m/K (kₜₕ), such as about 150, 285, 300, 400, 500, 600, 700, 800, 900, or 1000 W/m/K, and have high resistivity and breakdown field. By way of example but not limiting the present disclosure, the dielectric material may have a resistivity about 1×10¹⁴ ohm×cm, such as about 1×10¹⁴, 1×10¹⁵, 1×10¹⁶, or 1×10¹⁷ ohm×cm. The dielectric material may have a breakdown field greater than about 0.16 MV/cm, such as about 0.2, 0.3, or 0.31 MV/cm. In some embodiments, the dielectric material may include metal oxide (e.g., beryllium oxide (BeO)) or metal nitride (e.g., aluminum nitride (AlN)). In some embodiments, the dielectric material may include chemical vapor deposition (CVD) diamond. In some embodiments, the dielectric material is formed by a deposition process including a chemical vapor deposition (CVD) process, such as high density plasma CVD (HDP-CVD), flowable chemical vapor deposition (FCVD), the like, or a combination thereof. Other suitable materials formed by any acceptable process may be used to form the dielectric TSV 319a. In some embodiments, the TSV opening 329a is metal-free therein. Subsequently, the excess portions of the dielectric material are removed, either through etching, chemical mechanical polishing (CMP), or the like, forming the back-side surface 319s of the dielectric-filled opening substantially coplanar with the backside surface 302b of the substrate 302. The remaining portion of the dielectric material in the TSV opening 329a forms the dielectric TSV 319a.

In FIG. 1B, a number of the dielectric TSVs 319a is plurality and located on both sides of the gate structure 307. In some embodiments, the dielectric TSVs 319a can be located on a first side of the gate structure 307 rather than on a second side of the gate structure 307 opposite to the first side of the gate structure 307. By way of example but not limiting the present disclosure, as shown in FIG. 1E, two dielectric TSVs 419a can be located at both sides of a gate structure 407. Alternatively, as shown in FIG. 1F, the dielectric TSV 419a can be located at a first side (e.g. a side of the gate structure 407 adjacent to the source node) of the gate structure 407 rather than on a second side (e.g. a side of the gate structure 407 adjacent to the drain node) of the gate structure 407 opposite to the first side of the gate structure 407. Alternatively, as shown in FIG. 1G, the dielectric TSV 419a can be located at the second side of the gate structure 407 rather than on the first side of the gate structure 407. In a self-heating simulation on the structures of FIGS. 1E-1G compared with the structures without dielectric TSV, the structure of FIG. 1E can have a temperature reduction about 70° C. the structure of FIG. 1F can have a temperature reduction about 47° C., and the structure of FIG. 1G can have a temperature reduction about 58° C. That is, the semiconductor structure having a dielectric TSV adjacent to the drain node may have a greater temperature reduction than adjacent to the source node. In addition, the semiconductor structure with dielectric TSVs on both sides of the gate structure may have an improved temperature reduction than the structure with dielectric TSV on one side of the gate structure.

FIGS. 1E to 1G illustrate schematic cross-sectional views of semiconductor structures with transistors in accordance with some embodiments of the present disclosure. While FIGS. 1F and 1G show embodiments of semiconductor structures with different thermal dissipation paths than the semiconductor structure in FIG. 1E. In addition, the present disclosure may repeat reference numerals and/or letters in the various examples. This repetition is for the purpose of simplicity and clarity and does not in itself dictate a relationship between the various embodiments and/or configurations discussed. In some embodiments, the transistors may be GAA FETs. The silicon channel regions of the transistors are formed by semiconductor sheets 403. The semiconductor sheets 403 are stacked along the Z-direction over a semiconductor fin 401 on the front-side surface 402f of a substrate 402 and are wrapped by a gate structure 407 including a gate dielectric layer 407a, a work function layer 407b, and a gate electrode layer 407c in sequence. The Z-direction is perpendicular to the plane formed by the X-direction and Y-direction. Source/drain regions 415 are formed on opposite sides of the semiconductor sheets 403. Source/drain contacts 412 are on the source/drain regions 415. Silicide layer 416 can be formed between the source/drain contacts 412 and the source/drain regions 415 for Rc reduction. Gate spacers 417 are formed on the sidewalls of the gate structure 407. In some embodiments, the gate spacer 417 may be made of silicon nitride or silicon oxynitride, although any suitable material, such as low-dielectric constant (low-k) materials having a k-value less than about 3.5, may be utilized. Inner spacers 418 can act as isolation features and may be formed between the source/drain regions 415 and the gate electrode layer 407c. An inter-layer dielectric (ILD) layer 411 is formed over the gate structure 407 and the source/drain regions 415. In some embodiments, the ILD layer 411 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like, which may be formed by a chemical vapor deposition (CVD) process, such as high density plasma CVD (HDP-CVD), flowable chemical vapor deposition (FCVD), the like, or a combination thereof.

Referring back to FIG. 1A, a TSV 319b are formed through the substrate 302, the STI region 305, and the ILD layer 313 and in contact with the contact 312, and a TSV 319c is formed through the substrate 302 and having a front-side surface 319r in contact with the buried power rail 318. In some embodiments, the TSV 319b can be interchangeably referred to as a signal nano TSV (PDN nTSV), and the TSV 319c can be interchangeably referred to as a power delivery node nano TSV (PDN nTSV). Specifically, the formation of the TSVs 319b and 319c is to form TSV openings 329b and 329c firstly. Specifically, operations for forming the TSV openings 329b and 329c are substantially the same as the operations for forming the TSV opening 329a described in foregoing descriptions and thus are not repeated herein for the sake of clarity. The TSV opening 329b is formed through the substrate 302. STI region 305, and ILD layer 313 until reaching the contact 312 that is connected to signal, power, or ground. The TSV opening 329c is formed through the substrate 302 until reaching the buried power rail 318 that is connected to power or ground. In some embodiments, the forming of the TSV opening 329b may be simultaneously performed with the forming of the TSV opening 329a, such that a front-side of the TSV opening 329b may be level with a front-side of the TSV opening 329a. In some embodiments, the forming of the TSV opening 329c may be performed prior to or after the forming of the TSV opening 329a, such that a front-side of the TSV opening 329c may not be level with the front-side of the TSV opening 329a.

Subsequently, the TSV 319b is formed in the TSV opening 329b and in contact with the contact 312 to connect to the signal, power, or ground, and the TSVs 319c is formed in the TSV opening 329c of the substrate 302 and in contact with the buried power rail 318 to connect to the power or ground. In greater detail, the TSVs 319b and 319c are formed by using a metallization process as well as the use of metal electroplating techniques to fill high aspect ratio openings to avoid a seam or void defect. In some embodiments, in order to avoid diffusion of metal from the TSV metal into the silicon substrate, barrier layers 339b and 339c are used between the insulation layer and the TSV metal. The barrier layers 339b and 339c may line the TSV openings 319b and 319c. The barrier layers 339b and 339c functions as diffusion barriers to prevent metal diffusion and as adhesion layers between metal and dielectric. By way of example but not limitation, refractory metals, refractory metal-nitrides, refractory metal-silicon-nitrides and combinations thereof may be used for the barrier layers 339b and 339c, such as TaN, Ta, Ti, TiN, TiSiN, WN, or combinations thereof. In some embodiments, the barrier layers 339b and 339c may include TaN layers and Ta layers. In some embodiments, the barrier layers 339b and 339c may be TiN layers. In some embodiments, the barrier layers 339b and 339c may be Ti layers. In some embodiments, metal seed layers (not shown) may be then formed on the barrier layers 339b and 339c. In some embodiments, the metal seed layers may be a copper seed layer that may be formed by physical vapor deposition by way of example but not limitation. Subsequently, the semiconductor structure 300 may be transferred to a plating tool, such as an electrochemical plating (ECP) tool, and a conductive layer is plated on the wafer W1 by the plating process to fill the TSV openings 329b and 329c. While ECP process is described herein, the embodiment is not limited to ECP deposited metal. The conductive layer may include a low resistivity conductor material selected from the group of conductor materials including, but not limited to, copper and copper-based alloy. Alternatively, the conductive layer may comprise various materials, such as tungsten, ruthenium, aluminum, gold, silver, and the like. In some embodiments, the conductive layer is a copper-containing layer formed over the copper seed layer. Subsequently, the excess portions of the conductive layers, the metal seed layers, and the barrier layers 339b and 339c are removed, either through etching, chemical mechanical polishing (CMP), or the like, forming the upper surface of the metal-filled opening substantially coplanar with the backside surface 302b of the substrate 301. The remaining portions of the conductive layer and the barrier layers 339b and 339c in the TSV openings 329b and 329c form the TSVs 319b and 319c.

In some embodiments, the TSV 319a, 319b, and/or 319c may have a rectangular plan-view profile (or top-view profile) as shown in FIG. 1B. Alternatively, the TSV 119c may have a circular plan-view profile, an ellipse plan-view profile, or a diamond plan-view profile. In some embodiments, the TSV 319a, 319b, and/or 319c may have a lateral dimension in a range from about 10 nm to about 20 μm. In some embodiments, the TSV 319a, 319b, and/or 319c may have a vertical dimension in a range from about 50 nm to about 200 μm.

After forming the front-side interconnect structure 106a, the back-side interconnect structure 306b including multiple interconnect levels may be formed, stacked vertically over a back-side of the substrate 302 by using the BEOL scheme as illustrated in FIG. 1A. In some embodiments, the back-side interconnect structure 306b electrically interconnects the buried power rail 318 and the front-side interconnect structure 306a to form functional electrical circuits within the semiconductor structure 300. The back-side interconnect structure 306b may comprise one or more metallization layers 308b. In some embodiments, the number of the metallization layers may vary according to design specifications of the semiconductor structure 300. The metallization layers 308b comprise dielectric layers 310b and 311b, respectively. The dielectric layers 311b are formed over the corresponding dielectric layers 310b. The metallization layers 308b comprise one or more horizontal interconnects, such as conductive lines 314b, respectively extending horizontally or laterally in dielectric layers 311b and vertical interconnects, such as conductive vias 316b, respectively extending vertically in dielectric layers 310b. The back-side surface 319s of the dielectric TSV 319a and/or the back-side surface 319k of the dielectric TSV 319c can be in contact with the conductive line 314b. In some embodiments, the conductive line 314b can be interchangeably referred to as a metal line or a metal strip.

In some embodiments, the conductive lines 314b and the conductive vias 316b may be formed using any suitable method, such as a single damascene process, a dual damascene process, or the like. In some embodiments, the dielectric layers 310b and 311b may include low-k dielectric materials having k values, for example, lower than about 4.0 or even 2.0 disposed between such conductive features. In some embodiments, the dielectric layers may be made of, for example, phosphosilicate glass (PSG), borophosphosilicate glass (BPSG), fluorosilicate glass (FSG), SiOxCy, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The conductive lines 314b and the conductive vias 316b may comprise conductive materials such as copper, aluminum, tungsten, combinations thereof, or the like. In some embodiments, the conductive lines 314b, and the conductive vias 316b may further comprise one or more barrier/adhesion layers (not shown) to protect the respective dielectric layers 310b and 311b from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like. Formation of the back-side interconnect structure 306b can be referred to as a back-end-of-line (BEOL) process. In some embodiments, the TSVs 319a and 319c land on the innermost one of the conductive lines 314b in the metallization layers 308b of the back-side interconnect structure 306b.

Reference is made to FIGS. 1C and 1D. FIGS. 1C and 1D illustrate schematic top views of semiconductor structures corresponding to FIG. 1B according to some embodiments of the present disclosure. While FIGS. 1C and 1D show embodiments of semiconductor structures with different thermal dissipation paths than the semiconductor structure in FIGS. 1A and 1B. In addition, the present disclosure may repeat reference numerals and/or letters in the various examples. This repetition is for the purpose of simplicity and clarity and does not in itself dictate a relationship between the various embodiments and/or configurations discussed. It is noted that, the difference between the embodiment in FIG. 1C and the embodiment in FIGS. 1A and 1B is in that the dielectric TSV 319a is form on the back-side surface 318b (see FIG. 1A) of the buried power rail 318 as the TSV 319c. Therefore, the front-side of the dielectric TSV 319a can be level with the front-side of the dielectric TSV 319c at the back-side surface of the buried power rail 318b. In addition, the difference between the embodiment in FIG. 1D and the embodiment in FIGS. 1A and 1B is in that the dielectric TSV 319a is form on the back-side surface of the gate structure 307. In some embodiments, the layouts as shown in FIGS. 1B-1D are represented by a plurality of masks generated by one or more processors and/or stored in one or more non-transitory computer-readable media. Other formats for representing the layout are within the scope of various embodiments. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

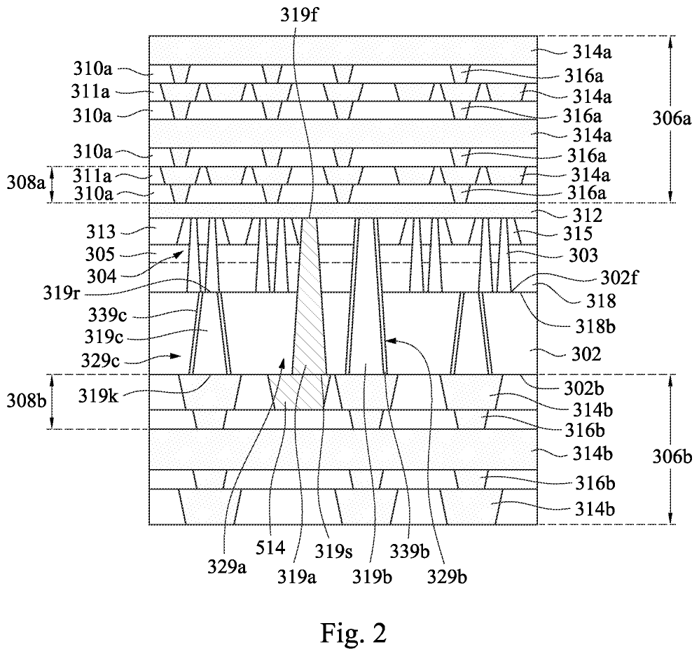

Reference is made to FIG. 2. FIG. 2 illustrates a schematic cross-sectional view of semiconductor structures in accordance with some embodiments of the present disclosure. While FIG. 2 shows an embodiment of a semiconductor structure with a different thermal dissipation path than the semiconductor structure in FIGS. 1A and 1B. In addition, the present disclosure may repeat reference numerals and/or letters in the various examples. This repetition is for the purpose of simplicity and clarity and does not in itself dictate a relationship between the various embodiments and/or configurations discussed. It is noted that, the difference between the embodiment in FIG. 2 and the embodiment in FIGS. 1A and 1B is in that an additional dielectric layer 514 is formed on the back-side 303b of the substrate 303 and in a same level height as the innermost one of the conductive lines 314b in the metallization layers 308b of the back-side interconnect structure 306b. The back-side surface 319s of the TSV 319a is in contact with the dielectric layer 514, such that the TSV 319a and the dielectric layer 514 can be served as a thermal dissipation path that connects metal layers on wafer front-side and wafer back-side.

In some embodiments, the dielectric layer 514 may be made of a dielectric material may have a thermal conductivity greater than about 150 W/m/K (kₜₕ). In some embodiments, the dielectric layer 514 may include metal oxide (e.g., beryllium oxide (BeO)) or metal nitride (e.g., aluminum nitride (AlN)). In some embodiments, the dielectric layer 514 may include chemical vapor deposition (CVD) diamond. In some embodiments, the dielectric layer 514 is formed by a deposition process including a chemical vapor deposition (CVD) process, such as high density plasma CVD (HDP-CVD), flowable chemical vapor deposition (FCVD), the like, or a combination thereof. Other suitable materials formed by any acceptable process may be used to form the dielectric layer 514. In some embodiments, the dielectric layer 514 is metal-free. For example, the dielectric layer 514 can be made of metal oxide (e.g., beryllium oxide (BeO)), metal nitride (e.g., aluminum nitride (AlN)), a combination thereof, or other suitable materials. In some embodiments, the dielectric layer 514 may be made of a same material as the TSV 319a. In some embodiments, the dielectric layer 514 may be made of a different material than the TSV 319a. In some embodiments, the dielectric layer 514 can be interchangeably referred to as a dielectric lateral structure.

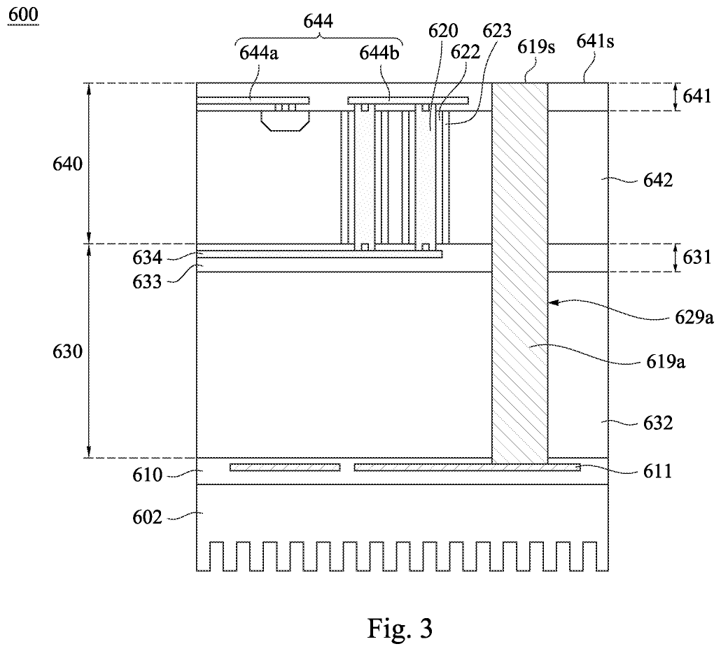

Reference is made to FIG. 3. FIG. 3 illustrates a schematic cross-sectional view of a semiconductor structure 600 in accordance with some embodiments of the present disclosure. In some embodiments, the semiconductor structure 600 may be a 3D packaging structure. As shown in FIG. 3, a redistribution structure 610 can be formed over a heat sink 602. In some embodiments, the redistribution structure 610 may include a dielectric layer and a patterned conductive layer 611 as redistribution conductive lines embedded in the dielectric layer. In some embodiments, one or more layers of dielectric materials are represented collectively as the dielectric layer, and the patterned conductive layer may be redistribution wirings that include vias, pads and/or traces that form the electrical connections. These redistribution wirings are formed layer by layer and stacked on the layers of dielectric materials alternately. In some embodiments, the dielectric layer may be formed of a polymeric material such as polybenzoxazole (PBO), polyimide (PI), benzocyclobutene (BCB), or other suitable material that can be patterned using lithography. For example, the dielectric layer may be formed using any suitable method, such as a spin-on coating process, a deposition process, and/or the like. In some embodiments, the patterned conductive layer may be formed of conductive material, e.g., copper, titanium, tungsten, aluminum, metal alloy, a combination of these, or the like). The numbers of the dielectric layer and the patterned conductive layer may be selected based on demand and are not limited in the disclosure. In some embodiments, the redistribution structure 610 can be interchangeably referred to as a redistribution layer.

A device package 630 may be provided and disposed over the redistribution structure 610. In FIG. 3, only one device package 630 is shown as an example, but it is understood that more than one semiconductor dies or different types of semiconductor dies may be included within the electronic device. In some embodiments, the device package 630 is formed in a device wafer, which may include different die regions that are singulated in subsequent steps to form a plurality of semiconductor dies 630. After singulation, the device package 630 is placed on the predetermined location by, for example, a pick-and-place process. In some embodiments, the device package 630 includes a semiconductor substrate 632 and a plurality of connectors 634 distributed over the semiconductor substrate 632. In some embodiments, the device package 630 is attached to the redistribution structure 610 via a die attach film DAF that is disposed on the device package 630 for better adhering the device package 630 to the redistribution structure 610. Alternatively, the die attach film DAF is omitted. The connectors are 634 disposed over the redistribution structure 610 for further electrical connection.

The semiconductor substrate 632 may include a bulk semiconductor substrate, semiconductor-on-insulator (SOI) substrate, multi-layered semiconductor substrate, etc. The semiconductor material of the semiconductor substrate 632 may be silicon, germanium, a compound semiconductor (e.g., silicon carbide, silicon germanium, gallium arsenic, gallium phosphide, indium phosphide, etc.), an alloy semiconductor (e.g., SiGe, GaAsP. AlInAs, AlGaAs, etc.), or combinations thereof. The semiconductor substrate 632 may be doped or undoped. In some embodiments, multi-layered or gradient semiconductor substrates are used. The connectors 634 may be or may include conductive pads (e.g., aluminum pads, copper pads or other suitable metallic pads) and/or conductive posts (e.g., copper posts or copper alloy posts). It is noted that the illustration of the device package 630 is simplified and multiple layers and/or components may be included within the device package 630. The connectors 634 and the dielectric layers 633 over the semiconductor substrate 632 are formed in a back end of line (BEOL) process, and can be interchangeably referred to as a BEOL structure 631.

In some embodiments, the device package 630 includes integrated passive devices (IPDs). In other embodiments, the device package 630 includes active component (e.g., transistors or the like) and/or passive components (e.g., resistors, capacitors, inductors, etc.) formed in and/or on the semiconductor substrate 632. For example, the device package 630 includes one or more types of dies selected from application-specific integrated circuit (ASIC) dies, analog dies, sensor dies, wireless and radio frequency dies, voltage regulator dies or memory dies. In some embodiments, the device package 630 is a bridge die (e.g., a silicon bridge) that may be free of active components and/or passive components. In other embodiments, the device package 630 serving as the silicon bridge includes passive components, but no active component is built therein.

A device package 640 may be provided and disposed over the device package 630. The device package 640 may be electrically coupled to the device package 630 through the connectors 634. In FIG. 3, only one device package 640 is shown as an example, but it is understood that more than one semiconductor dies or different types of semiconductor dies may be included within the electronic device. In some embodiments, the device package 640 includes a semiconductor substrate 642 and a plurality of connectors 644 distributed over the semiconductor substrate 642. The connectors are 644 disposed over the device package 630 for further electrical connection.

The semiconductor substrate 642 may include a bulk semiconductor substrate, semiconductor-on-insulator (SOI) substrate, multi-layered semiconductor substrate, etc. The semiconductor material of the semiconductor substrate 642 may be silicon, germanium, a compound semiconductor (e.g., silicon carbide, silicon germanium, gallium arsenic, gallium phosphide, indium phosphide, etc.), an alloy semiconductor (e.g., SiGe, GaAsP, AlInAs, AlGaAs, etc.), or combinations thereof. The semiconductor substrate 642 may be doped or undoped. In some embodiments, multi-layered or gradient semiconductor substrates are used. The connectors 644 may be or may include conductive pads (e.g., aluminum pads, copper pads or other suitable metallic pads) and/or conductive posts (e.g., copper posts or copper alloy posts). It is noted that the illustration of the device package 640 is simplified and multiple layers and/or components may be included within the device package 640. The connectors 644 and the dielectric layers 643 are formed in a back end of line (BEOL) process, and can be interchangeably referred to as a BEOL structure 641. The connectors 644 may include a ground line 644a and a signal line 644b. The signal line 644b of the connectors 644 in the device package 640 can be electrically connected to the connectors 634 in the device package 630 through a TSV 620. The TSV 619a can be interchangeably referred to as a signal TSV. The TSV 619a is separated from the semiconductor substrate 632 by a liner 622 that laterally surrounds the TSV 620. In some embodiments, the TSV 620 is conductive and may be or comprise an electrically conductive material, such as copper, aluminum, some other suitable metal(s), the like, or combinations thereof. In some embodiments, the liner 622 may be made of a dielectric material, such as silicon oxide, silicon nitride, the like, or other suitable dielectric(s). In addition, a depletion region 623 is formed to laterally surround the TSV 620 and block the migration of charge to the semiconductor substrate 642 from proximate the TSV 620.

In some embodiments, the device package 640 includes integrated passive devices (IPDs). In other embodiments, the device package 640 includes active component (e.g., transistors or the like) and/or passive components (e.g., resistors, capacitors, inductors, etc.) formed in and/or on the semiconductor substrate 642. For example, the device package 640 includes one or more types of dies selected from application-specific integrated circuit (ASIC) dies, analog dies, sensor dies, wireless and radio frequency dies, voltage regulator dies or memory dies. In some embodiments, the device package 640 is a bridge die (e.g., a silicon bridge) that may be free of active components and/or passive components. In other embodiments, the device package 640 serving as the silicon bridge includes passive components, but no active component is built therein. It is noted that device packages shown in FIG. 3 is an illustrative example, and other three-dimensional integrated circuit (3DIC) packages may be used. For example, the device package 630 or the device package 640 may include a chip-on-wafer (CoW) package, a flip-chip package, a package-on-package (POP) structure, etc. It is appreciated that the device packages 630 and 640 in FIG. 3 are illustrated in a simplified manner, and various features and layers may be omitted. It is also appreciated that the number of device packages shown in FIG. 3 is an illustrative example, and a single device package or more than one device packages may be disposed on the redistribution structure 610. The number of the device packages and the mounting method of the device packages are not limited in the disclosure.

As shown in FIG. 3, a dielectric TSV 619a is formed through the device packages 630 and 640 and in contact with a conductive metal line (not shown) in the redistribution structure 610. The dielectric TSV 619a may be used act as a thermal path to relieve the thermal in the circuits. In some embodiments, the dielectric TSV 619a can be interchangeably referred to as a thermal nano TSV (thermal nTSV). The TSV 619a that is made of a dielectric material having a higher thermal conductivity than the semiconductor substrates 632 and 642 to improve heat dissipation of the semiconductor structure 600. The TSV 619a can be metal-free. That is, the dielectric TSV 619a may be used to act as a heat sink for the semiconductor structure 600 to discharge the heat generated by the semiconductor device from a circuit local hotspot to outside of the semiconductor structure 600. In some embodiments, the thermal conductivity of the dielectric TSV 619a may be greater than about 150 W/m/K (kₜₕ). Because the dielectric TSV 619a can be metal-free, no parasitic capacitance will be generated in the semiconductor structure 600 around the dielectric TSV 619a, which in turn prevents an additional leakage path in the semiconductor structure 600, and thus the performance of the semiconductor structure 600 can be improved.

Specifically, the formation of the dielectric TSV 619a is to form a TSV opening 629a passing through the device packages 630 and 640 until reaching the patterned conductive layer in the redistribution structure 610. In defining the TSV opening 629a, a hard mask layer (not shown) is formed over the device package 640 followed by forming a patterned photoresist layer (not shown) thereon. The hard mask layer may be a silicon nitride layer, a silicon oxynitride layer or the like by way of example but not limitation. The photoresist layer is patterned by exposure, bake, developing, and/or other photolithography processes to provide an opening exposing the hard mask layer. The exposed hard mask layer is then etched, by a wet etch or dry etch process, using the patterned photoresist layer as a masking element to provide an opening. Using the hard mask layer and the patterned photoresist layer as mask elements, an etching process is performed to etch the exposed portions of the device packages 630 and 640, and form the TSV opening 329a passing through the device packages 630 and 640. The patterned conductive layer in the redistribution structure 610 may also act as an etch stop layer for etching the device packages 630 and 640 until the patterned conductive layer in the redistribution structure 610 is exposed. In some embodiments, the TSV opening 629a may be formed by performing any suitable etching process including, for example, a deep reactive ion etching (RIE) process, a plasma etch, a chemical wet etch, a laser drill, and/or other processes.

Subsequently, the dielectric TSV 619a is formed in the TSV opening 629a and in contact with the patterned conductive layer in the redistribution structure 610. Specifically, a dielectric material is deposited over the device package 640 and fills in the TSV opening 629a. In some embodiments, the dielectric material may have a thermal conductivity greater than about 150 W/m/K (kₜₕ). In some embodiments, the dielectric material may include metal oxide (e.g., beryllium oxide (BeO)) or metal nitride (e.g., aluminum nitride (AlN)). In some embodiments, the dielectric material may include chemical vapor deposition (CVD) diamond. In some embodiments, the dielectric material is formed by a deposition process including a chemical vapor deposition (CVD) process, such as high density plasma CVD (HDP-CVD), flowable chemical vapor deposition (FCVD), the like, or a combination thereof. Other suitable materials formed by any acceptable process may be used to form the dielectric TSV 619a. In some embodiments, the TSV opening 629a is metal-free therein. Subsequently, the excess portions of the dielectric material are removed, either through etching, chemical mechanical polishing (CMP), or the like, forming the surface 619s of the dielectric-filled opening substantially coplanar with the surface 641s of the BEOL structure 641. The remaining portion of the dielectric material in the TSV opening 629a forms the dielectric TSV 619a.

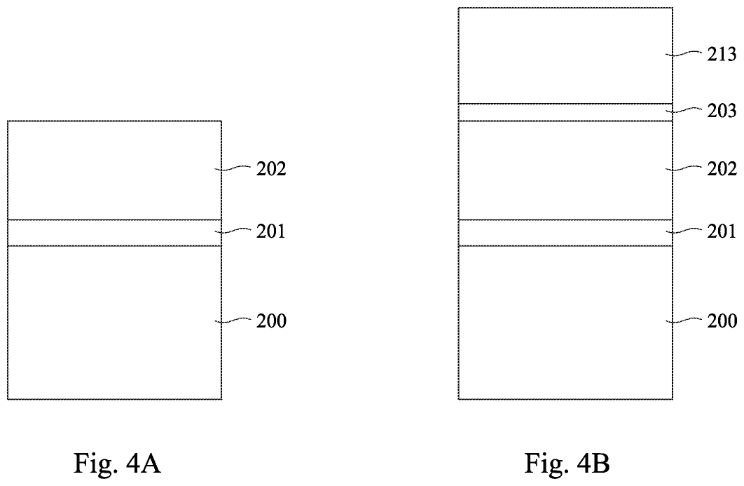

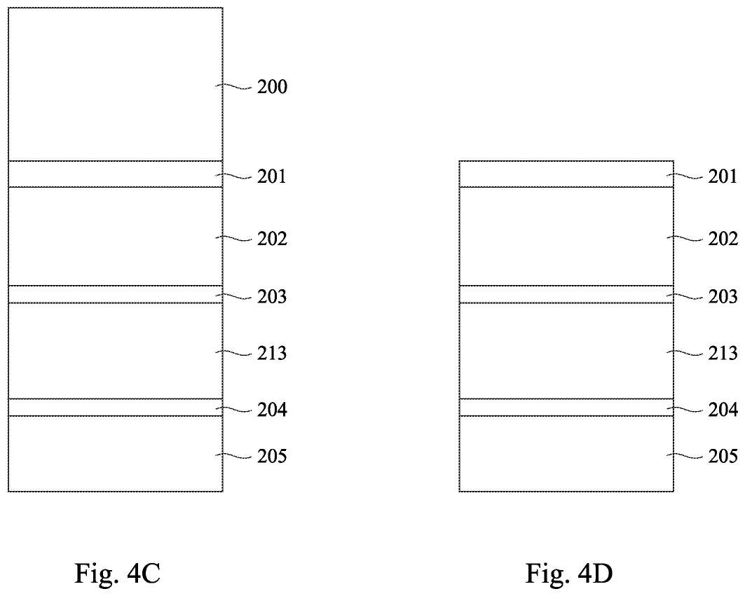

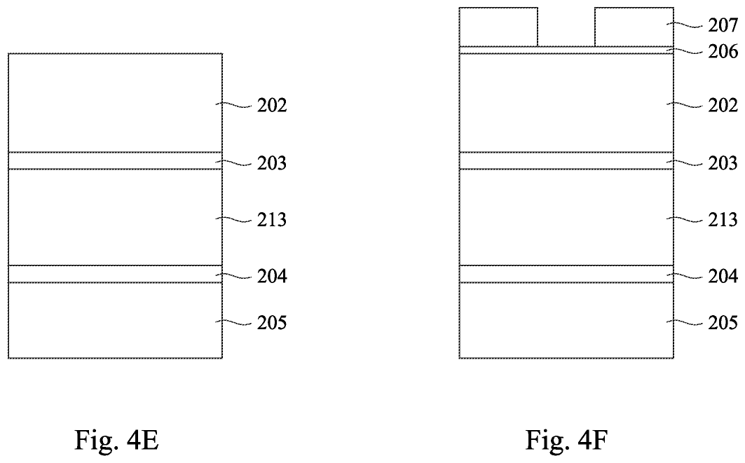

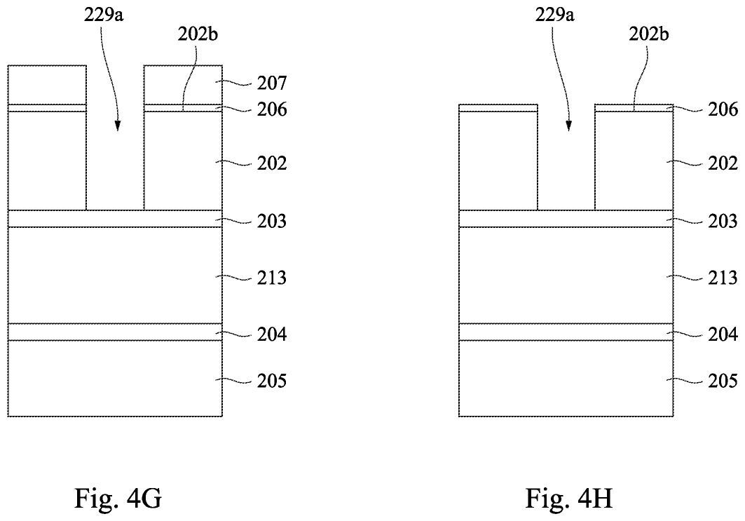

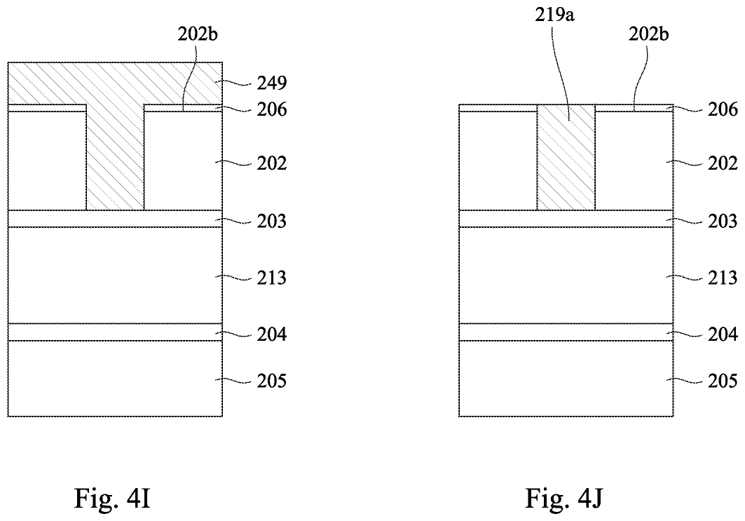

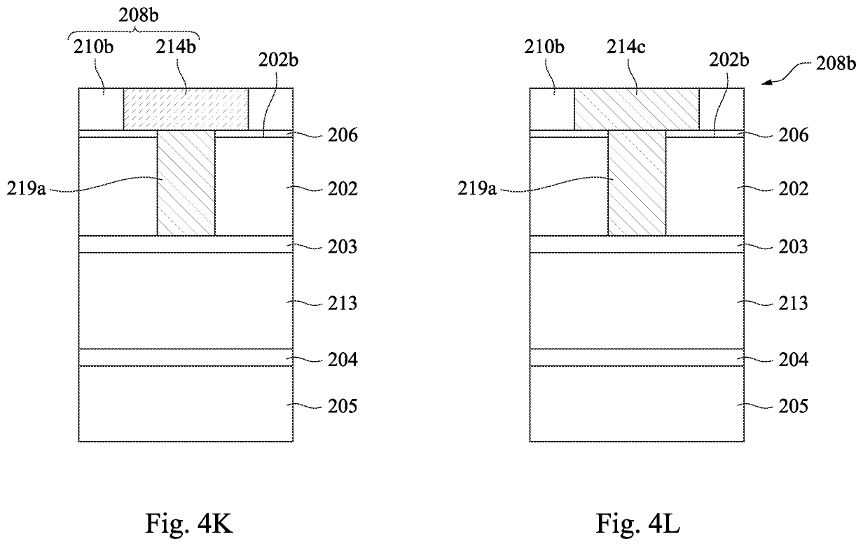

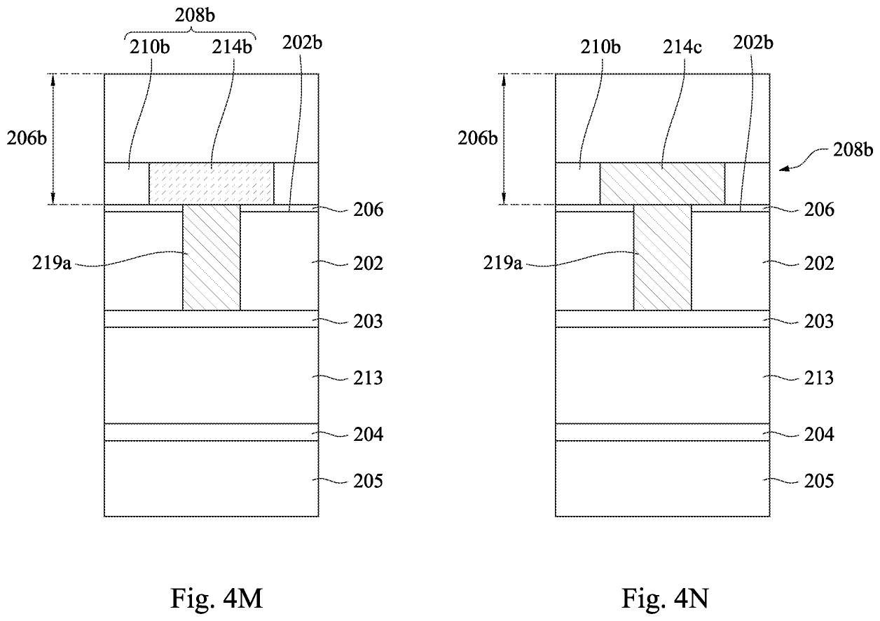

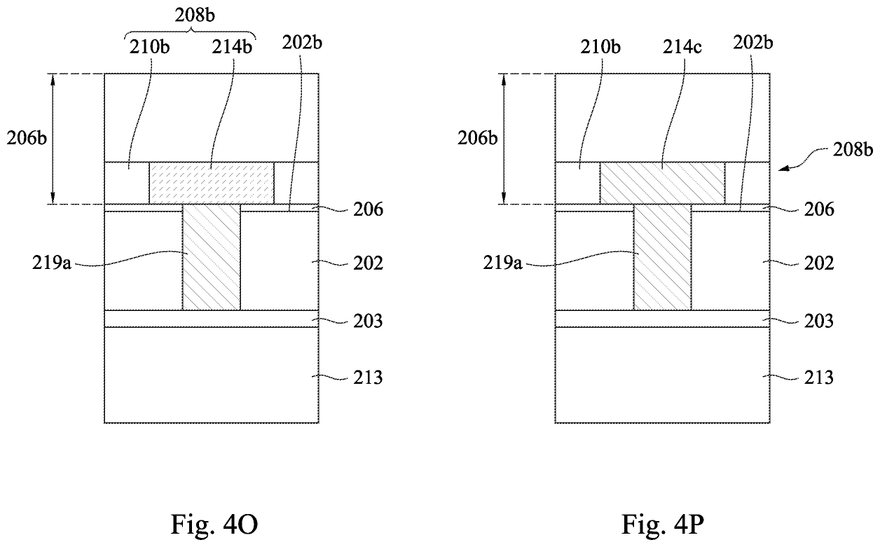

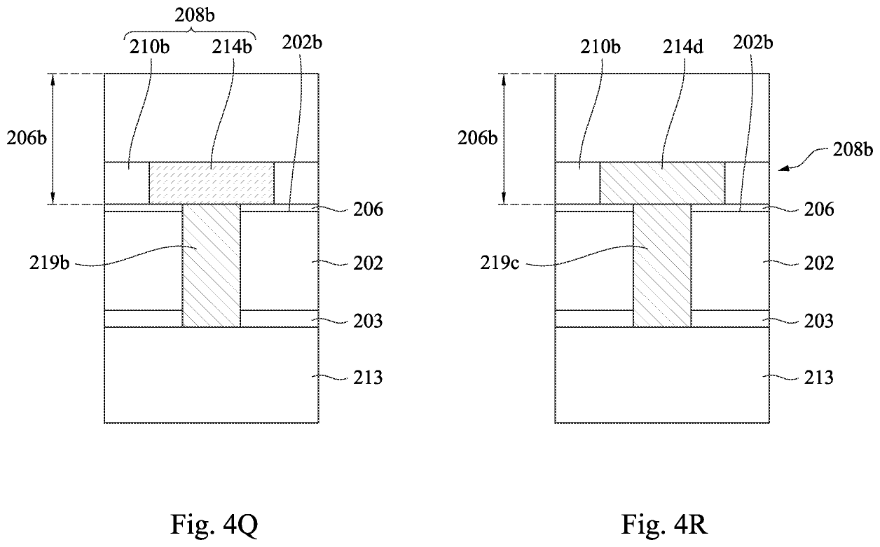

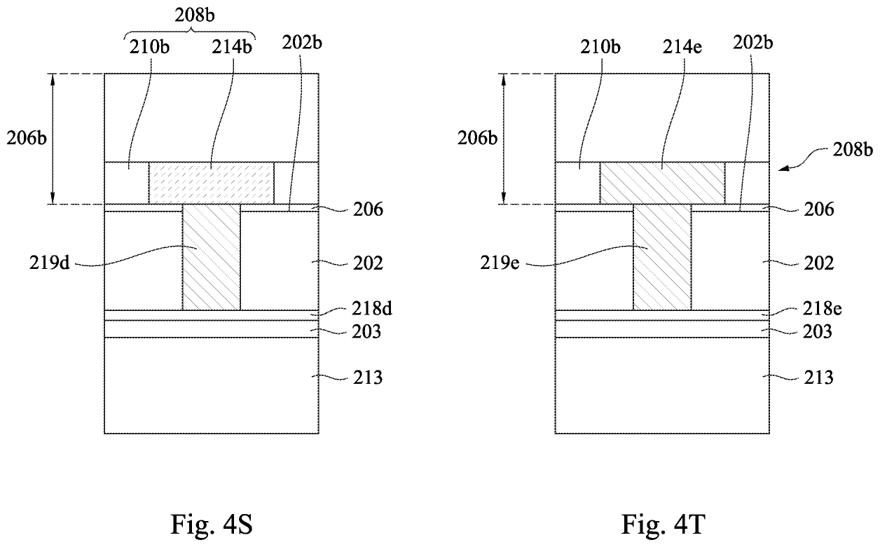

Reference is made to FIGS. 4A-4L, 4N, and 4P. FIGS. 4A-4L, 4N, and 4P illustrate cross-sectional views of intermediate stages in the formation of a semiconductor structure in accordance with some embodiments.

Reference is made to FIG. 4A. An etch stop layer 201 is formed over the substrate 200. Subsequently, a capping layer 202 is formed over the etch stop layer 201. In some embodiments, the substrate 200 may comprise, for example, bulk silicon, thin film, pre-pattern devices, doped or undoped, or an active layer of a semiconductor-on-insulator (SOI) substrate. The substrate 200 may be in the form of a wafer, and may have a round top-view shape or a rectangular top-view shape. The diameter of substrate 200 may be 3 inch, 12 inch, or greater. The etch stop layer 201 may be made of a material (e.g., SiGe) that has a high etching selectivity relative to the substrate 200 and the capping layer 202. In some embodiments, the capping layer 202 may be mad of a semiconductive material, such as silicon.

Reference is made to FIG. 4B. A FEOL structure 203 is formed over the capping layer 202. Subsequently, A BEOL structure 213 is formed over the FEOL structure 203. Material and manufacturing method for forming the BEOL structure 213 and FEOL structure 203 are substantially the same as the material and manufacturing method for forming the interconnect structure 306a and the formation of the structure prior to the front-side interconnect structure 306a described in foregoing descriptions and thus are not repeated herein for the sake of clarity.

Reference is made to FIG. 4C. The structure of FIG. 4B is “flipped” upside down, and is bonded to a carrier wafer 205 through a bonding dielectric 204. In some embodiments, the carrier wafer 205 may comprise, for example, bulk silicon, thin film, pre-pattern devices, doped or undoped, or an active layer of a semiconductor-on-insulator (SOI) substrate. The carrier wafer 205 may have a round top-view shape or a rectangular top-view shape. The diameter of the carrier wafer 205 may be 3 inch, 12 inch, or greater. In some embodiments, the bonding dielectric 204 may be made of a dielectric material, such as SiCN.

Reference is made to FIG. 4D. The substrate 200 is removed in a plurality of process operations, for example, CMP, HNA, and/or TMAH etching from the back-side of the substrate 200, which stops at the etch stop layer 201. After the removal process, the etch stop layer 201 is exposed as shown in FIG. 4D.

Reference is made to FIG. 4E. The etch stop layer 201 is removed in a plurality of process operations, for example, CMP, HNA, and/or TMAH etching from the back-side of the substrate 200, which stops at the capping layer 202. After the removal process, the capping layer 202 is exposed as shown in FIG. 4E. The etch stop layer 201 can be removed by any acceptable etching process that selectively etches the material of the etch stop layer 201 at a faster rate than the material of the capping layer 202. The etching may be isotropic. For example, when the etch stop layer 201 are formed of silicon germanium and the capping layer 202 are formed of silicon, the etching process may be a wet etch using tetramethylammonium hydroxide (TMAH), ammonium hydroxide (NH₄OH), or the like.

Reference is made to FIG. 4F. A hard mask layer 206 is formed over the capping layer 202. Subsequently, a patterned photoresist layer 207 is formed over the hard mask layer 206. In some embodiments, the hard mask layer 206 may be a silicon nitride layer, a silicon oxynitride layer or the like by way of example but not limitation, using low-pressure chemical vapor deposition (LPCVD) or plasma enhanced chemical vapor deposition (PECVD). The hard mask layer 206 is used as a hard mask during subsequent photolithography processes. The photoresist layer 207 is formed on the hard mask layer 206 and is then patterned, forming openings in the photoresist layer 207, so that regions of the hard mask layer 206 are exposed. In some embodiments, the photoresist layer 207 is patterned by exposure, bake, developing, and/or other photolithography processes to provide an opening exposing the hard mask layer 206.

Reference is made to FIG. 4G. Using the hard mask layer 206 and the patterned photoresist layer 207 as mask elements, an etching process is performed to etch the exposed capping layer 202, and the TSV opening 229a is formed to pass through the capping layer 202. In some embodiments, the TSV opening 329a may be formed by performing any suitable etching process including, for example, a plasma etch, a chemical wet etch, a laser drill, and/or other processes. In some embodiments, the etching process includes a deep reactive ion etching (RIE) process to etch the capping layer 202 from a backside surface 202b of the capping layer 202. After the etching process, a pre-cleaning process may be performed to clean the TSV opening 329a with hydrofluoric acid (HF) or other suitable solution in some embodiments.

Reference is made to FIG. 4H. After etching the capping layer 202, the photoresist layer 207 is removed. Next, a cleaning step may be optionally performed to remove a native oxide of the capping layer 202. The cleaning may be performed using diluted hydrofluoric (HF) acid, by way of example and not limitation.

Reference is made to FIGS. 41 and 4J. The dielectric TSV 219a (see FIG. 4J) is formed in the TSV opening 229a and in contact with metal element (not shown) in the FEOL structure 203 to connect to the signal, power, or ground, such that the TSV 219a can be served as a thermal dissipation path that connects metal layers on wafer front-side and wafer back-side. Specifically, a dielectric material 249 (see FIG. 4I) is deposited over the capping layer 202 from the back-side 202b of the capping layer 202 and fills in the TSV opening 229a. In some embodiments, the dielectric material 249 may have a thermal conductivity greater than about 150 W/m/K (kₜₕ). In some embodiments, the dielectric material 249 may include metal oxide (e.g., beryllium oxide (BeO)) or metal nitride (e.g., aluminum nitride (AlN)). In some embodiments, the dielectric material 249 may include chemical vapor deposition (CVD) diamond. In some embodiments, the dielectric material 249 is formed by a deposition process including a chemical vapor deposition (CVD) process, such as high density plasma CVD (HDP-CVD), flowable chemical vapor deposition (FCVD), the like, or a combination thereof. Other suitable materials formed by any acceptable process may be used to form the dielectric TSV 219a. In some embodiments, the TSV opening 229a is metal-free therein. Subsequently, the excess portions of the dielectric material 249 are removed, either through etching, chemical mechanical polishing (CMP), or the like, forming the back-side surface 219s of the dielectric-filled opening substantially coplanar with the backside surface 202b of the capping layer 202. The remaining portion of the dielectric material 249 in the TSV opening 229a forms the dielectric TSV 219a.

Reference is made to FIGS. 4K and 4M. A back-side interconnect structure 206b (see FIG. 4M) including multiple interconnect levels may be formed, stacked vertically over a back-side of the capping layer 202 by using the BEOL scheme as illustrated in FIG. 1A. In some embodiments, the back-side interconnect structure 206b electrically interconnects the buried power rail (not shown) and the FEOL structure 203 to form functional electrical circuits within the semiconductor structure. The back-side interconnect structure 206b may comprise one at least one metallization layer 208b. In some embodiments, the number of the metallization layer may vary according to design specifications of the semiconductor structure. The metallization layer 208b comprises dielectric layer 210b. The metallization layer 208b comprises at least one horizontal interconnect 214b extending horizontally or laterally in dielectric layers 210b. The interconnect 214b may be formed using any suitable method, such as a single damascene process, a dual damascene process, or the like. In some embodiments, the dielectric layer 210b may include low-k dielectric materials having k values, for example, lower than about 4.0 or even 2.0 disposed between such conductive features. In some embodiments, the dielectric layers may be made of, for example, phosphosilicate glass (PSG), borophosphosilicate glass (BPSG), fluorosilicate glass (FSG), SiOxCy, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The interconnect 214b may comprise conductive materials such as copper, aluminum, tungsten, combinations thereof, or the like. In some embodiments, the interconnect 214b may further comprise one or more barrier/adhesion layers (not shown) to protect the dielectric layer 210b from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like. Formation of the back-side interconnect structure 206b can be referred to as a back-end-of-line (BEOL) process. Subsequently, the carrier wafer 205 and the bonding dielectric 204 can be removed from the BEOL structure 213, as shown in FIG. 40.

Reference is made to FIGS. 4L, 4N, 4P, and 4Q-4T. FIGS. 4M, 4N, and 4P illustrate schematic cross-sectional views of a semiconductor structure corresponding to FIGS. 4K, 4M, and 40, respectively, according to some embodiments of the present disclosure. FIGS. 4Q-4T illustrate schematic cross-sectional views of different semiconductor structures corresponding to FIG. 40 according to some embodiments of the present disclosure. While FIGS. 4L, 4N, 4P, and 4Q-4T show embodiments of semiconductor structures with different thermal dissipation paths than the semiconductor structure in FIGS. 4A-4L, 4N, and 4P. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 4L, 4N, and 4P, the difference between the embodiment in FIGS. 4K, 4M, and 40 and the embodiment in FIGS. 4A-4L, 4N, and 4P is in that an additional dielectric layer 214c is formed on the back-side 202b of the capping layer 202 and in a same level height as the innermost one of the interconnect 214b in the metallization layer 208b of the back-side interconnect structure 206b. The TSV 219a is in contact with the dielectric layer 214c, such that the TSV 219a and the dielectric layer 214c can be served as a thermal dissipation path that connects metal layers on wafer front-side and wafer back-side. In some embodiments, the dielectric layer 214c may be made of a dielectric material may have a thermal conductivity greater than about 150 W/m/K (kₜₕ). In some embodiments, the dielectric layer 214c may include metal oxide (e.g., beryllium oxide (BeO)) or metal nitride (e.g., aluminum nitride (AlN)). In some embodiments, the dielectric layer 214c may include chemical vapor deposition (CVD) diamond. In some embodiments, the dielectric layer 214c is formed by a deposition process including a chemical vapor deposition (CVD) process, such as high density plasma CVD (HDP-CVD), flowable chemical vapor deposition (FCVD), the like, or a combination thereof. Other suitable materials formed by any acceptable process may be used to form the dielectric layer 214c. In some embodiments, the dielectric layer 214c is metal-free. For example, the dielectric layer 214c can be made of metal oxide (e.g., beryllium oxide (BeO)), metal nitride (e.g., aluminum nitride (AlN)), a combination thereof, or other suitable materials. In some embodiments, the dielectric layer 214c may be made of a same material as the TSV 219a. In some embodiments, the dielectric layer 214c may be made of a different material than the TSV 219a. In some embodiments, the materials chosen for the dielectric layer 214c and TSV 219a can be compatible with the manufacturing processes of the semiconductor structure. Some materials may be easier to deposit or etch than others, affecting the complexity and cost of manufacturing. In some embodiments, the dielectric layer 214c can be interchangeably referred to as a dielectric lateral structure.

As shown in FIGS. 4Q and 4R, the difference between the embodiments in FIGS. 4Q and 4R and the embodiment in FIGS. 4A-4L, 4N, and 4P is in that TSV 219b (see FIG. 4Q)/TSV 219c (see FIG. 4Q) further extends to the BEOL structure 213, such that the TSV 219b/TSV 219c can be served as a thermal dissipation path that connects metal layers on wafer front-side and wafer back-side. In addition, the semiconductor shown in FIG. 4Q has an additional dielectric layer 214d formed over the back-side 203b of the capping layer 202 and in a same level height as the innermost one of the interconnect 214b in the metallization layer 208b of the back-side interconnect structure 206b than the semiconductor shown in FIGS. 4A-4L, 4N, and 4P. Material and manufacturing method for forming the TSV 219b/TSV 219c and dielectric layer 214d are substantially the same as the material and manufacturing method for forming the TSV 219a and dielectric layer 214c described in foregoing descriptions and thus is not repeated herein for the sake of clarity.

As shown in FIGS. 4S and 4T, the difference between the embodiments in FIG. 4Q and the embodiment in FIGS. 4A-4L, 4N, and 4P is in that buried power rail 218d (see FIG. 4S)/buried power rail 218e (see FIG. 4T) is formed between the FEOL structure 203 and the back-side interconnect structure 206b. TSV 219d (see FIG. 4S)/TSV 219e (see FIG. 4T) further extends to the buried power rail 218d/buried power rail 218e, such that the TSV 219d/TSV 219e can be served as a thermal dissipation path that connects metal layers on wafer front-side and wafer back-side. In some embodiments, the buried power rail 218d/the buried power rail 218e may be form by forming a trench extending through the STI region in the FEOL structure 203 into the capping layer 202. Subsequently, a conductive material is filled in the trench to form the buried power rail 218d/the buried power rail 218e. The conductive material may include metal, such as tungsten (W), ruthenium (Ru), aluminum (Al), copper (Cu), or other suitable conductive material. In some embodiments, the conductive material 170 may be deposited by CVD, physical vapor deposition (PVD), sputter deposition, or other techniques suitable for depositing conductive materials. In addition, the semiconductor shown in FIG. 4T has an additional dielectric layer 214e formed over the back-side 203b of the capping layer 202 and in a same level height as the innermost one of the interconnect 214b in the metallization layer 208b of the back-side interconnect structure 206b than the semiconductor shown in FIGS. 4A-4L, 4N, and 4P. Material and manufacturing method for forming the TSV 219d/TSV 219e and dielectric layer 214e are substantially the same as the material and manufacturing method for forming the TSV 219a and dielectric layer 214c described in foregoing descriptions and thus is not repeated herein for the sake of clarity.

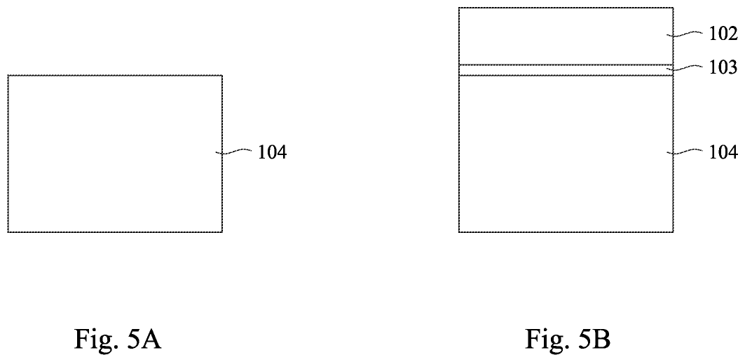

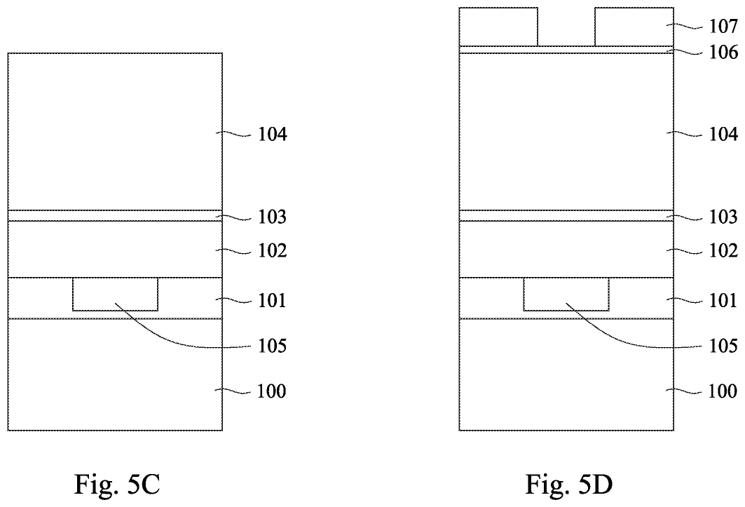

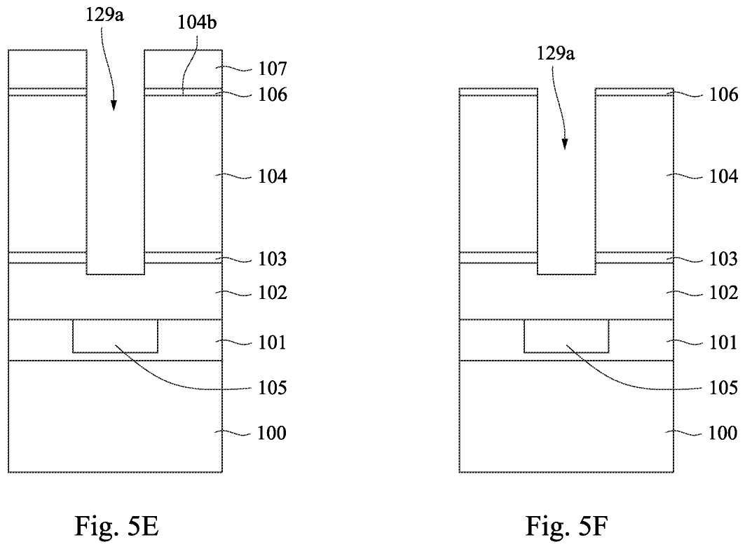

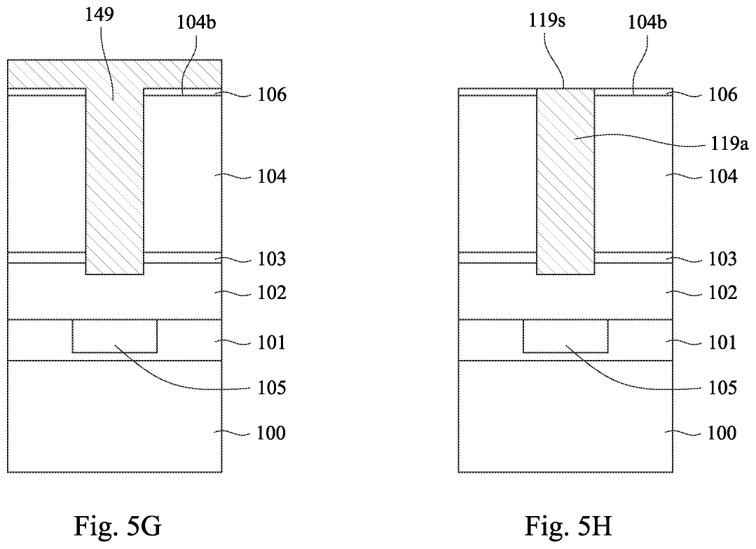

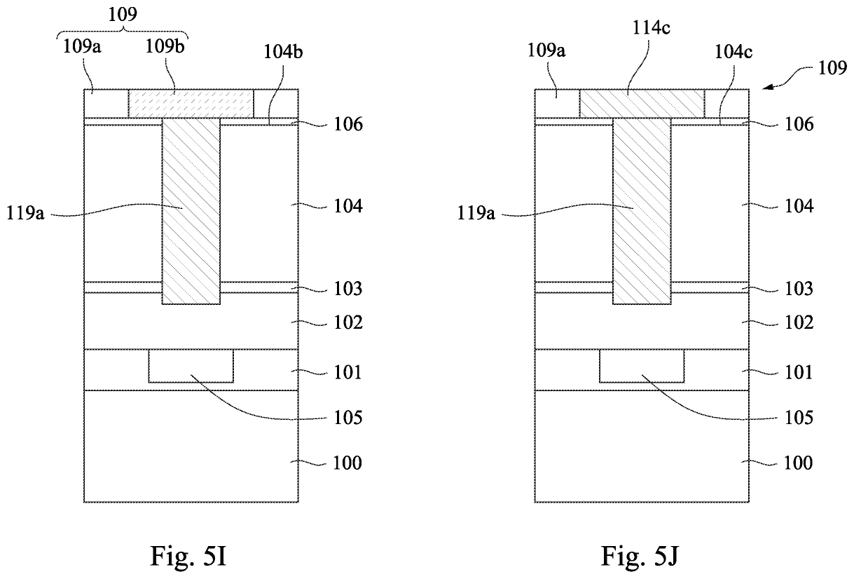

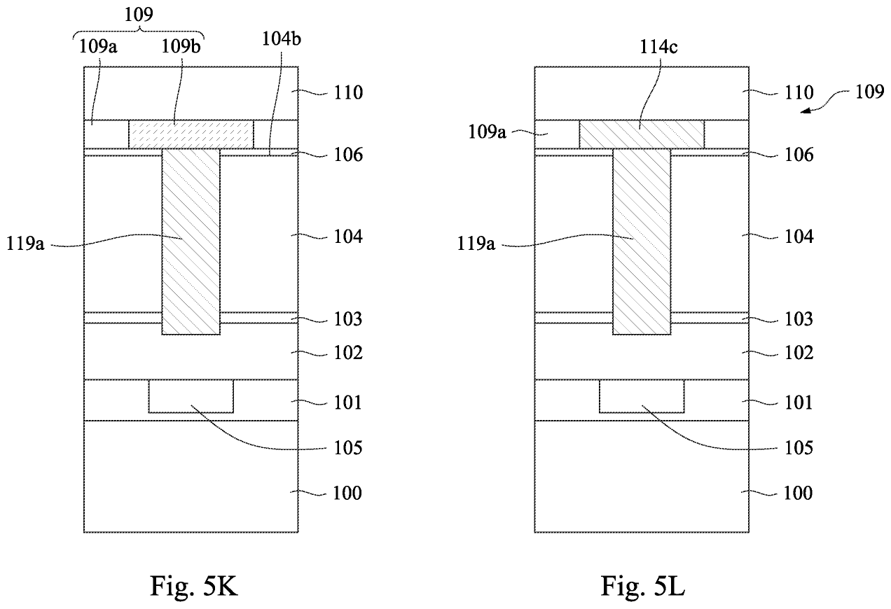

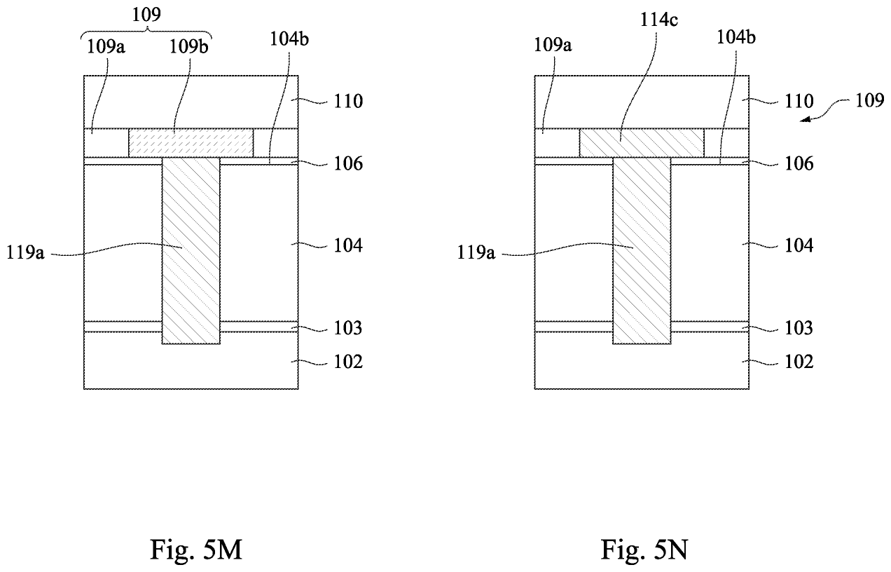

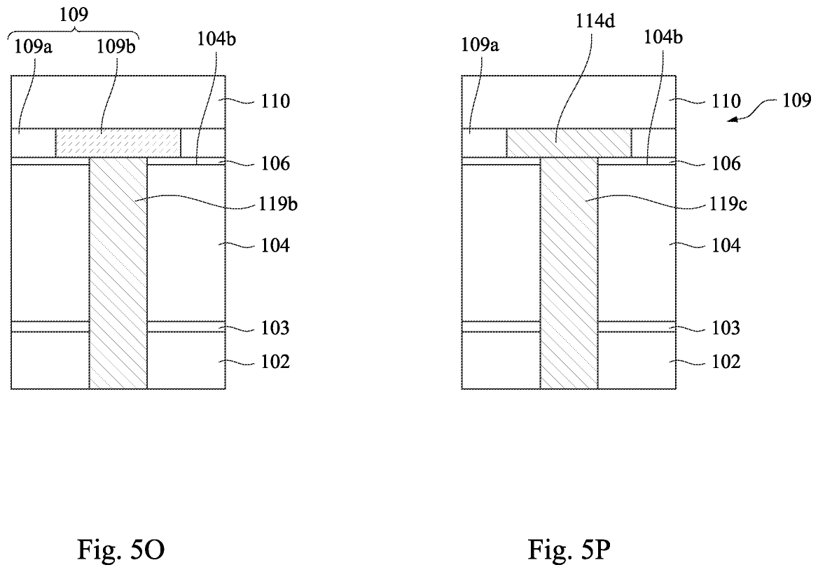

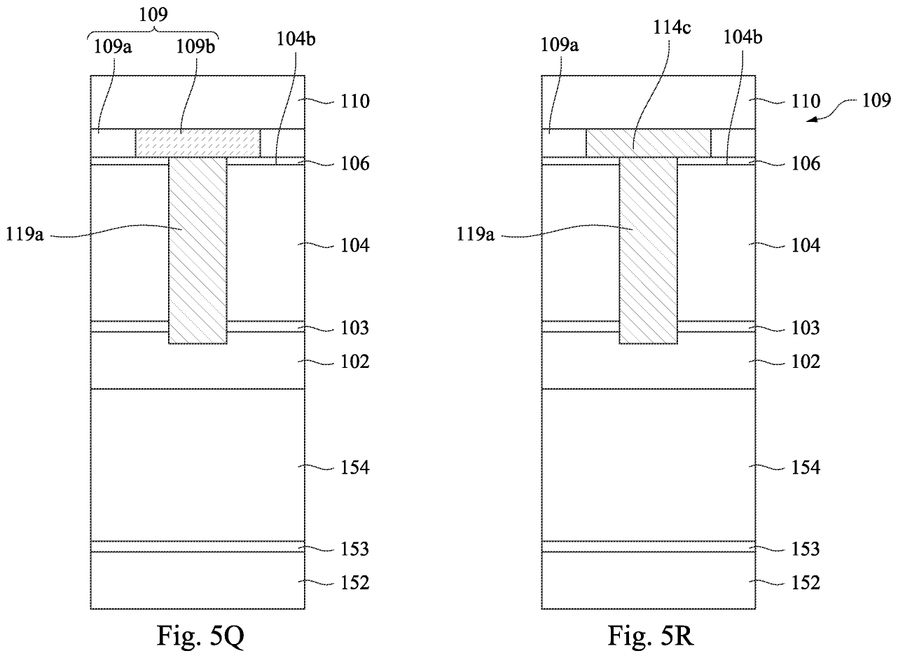

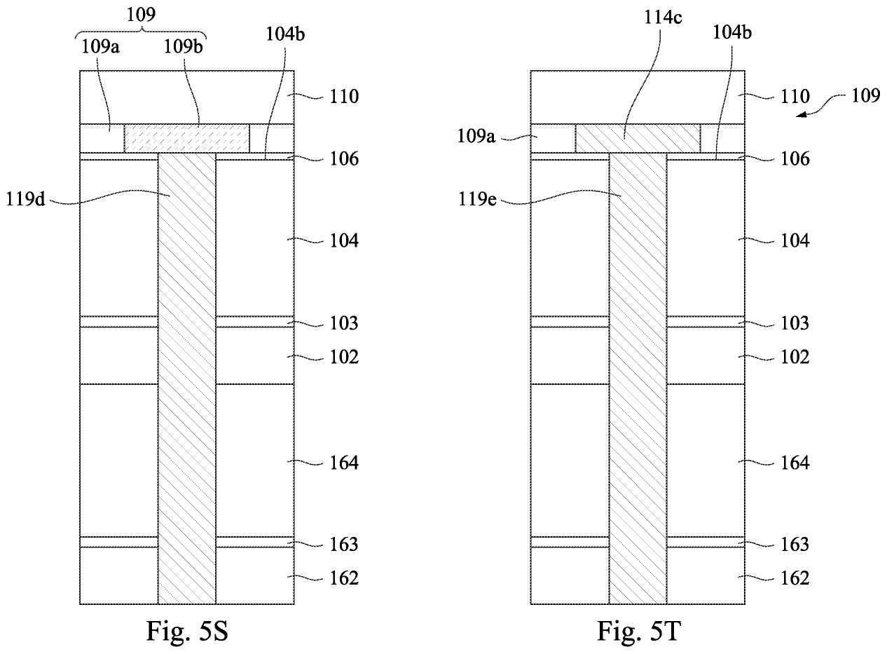

Reference is made to FIGS. 5A-51, 5K, and 5M. FIGS. 5A-51, 5K, and 5M illustrate cross-sectional views of intermediate stages in the formation of a semiconductor structure in accordance with some embodiments.

Reference is made to FIGS. 5A and 5B. A FEOL structure 103 (see FIG. 5B) is formed over a substrate 104. Subsequently, A BEOL structure 102 (see FIG. 5B) is formed over the FEOL structure 103. In some embodiments, the substrate 104 may be mad of a semiconductive material, such as silicon. Material and manufacturing method for forming the BEOL structure 102 and FEOL structure 103 are substantially the same as the material and manufacturing method for forming the interconnect structure 306a and the formation of the structure prior to the front-side interconnect structure 306a described in foregoing descriptions and thus are not repeated herein for the sake of clarity.

Reference is made to FIG. 5C. The structure of FIG. 5C is “flipped” upside down, and is bonded to a carrier wafer 100 through an adhesive material 101 having a bonding pad 105 therein, and the bonding pad 105 can be coupled to the BEOL structure 102. In some embodiments, the carrier wafer 100 may comprise, for example, bulk silicon, thin film, pre-pattern devices, doped or undoped, or an active layer of a semiconductor-on-insulator (SOI) substrate. The carrier wafer 100 may have a round top-view shape or a rectangular top-view shape. The diameter of the carrier wafer 100 may be 3 inch, 12 inch, or greater. In some embodiments, the adhesive material 101 may include a glue, laminate coating, foil, or other types of adhesive, as examples.

Reference is made to FIG. 5D. A hard mask layer 106 is formed over the substrate 104. Subsequently, a patterned photoresist layer 107 is formed over the hard mask layer 106. In some embodiments, the hard mask layer 106 may be a silicon nitride layer, a silicon oxynitride layer or the like by way of example but not limitation, using low-pressure chemical vapor deposition (LPCVD) or plasma enhanced chemical vapor deposition (PECVD). The hard mask layer 106 is used as a hard mask during subsequent photolithography processes. The photoresist layer 107 is formed on the hard mask layer 106 and is then patterned, forming openings in the photoresist layer 107, so that regions of the hard mask layer 106 are exposed. In some embodiments, the photoresist layer 107 is patterned by exposure, bake, developing, and/or other photolithography processes to provide an opening exposing the hard mask layer 106.

Reference is made to FIG. 5E. Using the hard mask layer 106 and the patterned photoresist layer 107 as mask elements, an etching process is performed to etch the exposed substrate 104 and the FEOL structure 103 until and a metal element (not shown) in the BEOL structure 102 is exposed, and the TSV opening 129a is formed to pass through the substrate 104. In some embodiments, the TSV opening 129a may be formed by performing any suitable etching process including, for example, a plasma etch, a chemical wet etch, a laser drill, and/or other processes. In some embodiments, the etching process includes a deep reactive ion etching (RIE) process to etch the substrate 104 from a backside surface 104b of the substrate 104. After the etching process, a pre-cleaning process may be performed to clean the TSV opening 129a with hydrofluoric acid (HF) or other suitable solution in some embodiments.

Reference is made to FIG. 5F. After etching the substrate 104, the photoresist layer 107 is removed. Next, a cleaning step may be optionally performed to remove a native oxide of the substrate 104. The cleaning may be performed using diluted hydrofluoric (HF) acid, by way of example and not limitation.

Reference is made to FIGS. 5G and 5H. The dielectric TSV 119a (see FIG. 5H) is formed in the TSV opening 129a and in contact with the metal element (not shown) in the BEOL structure 102 to connect to the signal, power, or ground, such that the TSV 119a can be served as a thermal dissipation path that connects metal layers on wafer front-side and wafer back-side. Specifically, a dielectric material 149 (see FIG. 5G) is deposited over the substrate 104 from the back-side 104b of the substrate 104 and fills in the TSV opening 129a. In some embodiments, the dielectric material 149 may have a thermal conductivity greater than about 150 W/m/K (kₜₕ). In some embodiments, the dielectric material 149 may include metal oxide (e.g., beryllium oxide (BeO)) or metal nitride (e.g., aluminum nitride (AlN)). In some embodiments, the dielectric material 149 may include chemical vapor deposition (CVD) diamond. In some embodiments, the dielectric material 149 is formed by a deposition process including a chemical vapor deposition (CVD) process, such as high density plasma CVD (HDP-CVD), flowable chemical vapor deposition (FCVD), the like, or a combination thereof. Other suitable materials formed by any acceptable process may be used to form the dielectric TSV 119a. In some embodiments, the TSV opening 129a is metal-free therein. Subsequently, the excess portions of the dielectric material 149 are removed, either through etching, chemical mechanical polishing (CMP), or the like, forming the back-side surface 119s of the dielectric-filled opening substantially coplanar with the backside surface 104b of the substrate 104. The remaining portion of the dielectric material 149 in the TSV opening 129a forms the dielectric TSV 119a.

Reference is made to FIG. 5I. A redistribution structure 109 can be formed over the back-side surface 104b of the substrate 104. In some embodiments, the redistribution structure 109 may include a dielectric layer 109a and a patterned conductive layer 109b embedded in the dielectric layer 109a. In some embodiments, one or more layers of dielectric materials are represented collectively as the dielectric layer 109a, and the patterned conductive layer 109b may be redistribution wirings that include vias, pads and/or traces that form the electrical connections. These redistribution wirings are formed layer by layer and stacked on the layers of dielectric materials alternately. In some embodiments, the dielectric layer 109a may be formed of a polymeric material such as polybenzoxazole (PBO), polyimide (PI), benzocyclobutene (BCB), or other suitable material that can be patterned using lithography. For example, the dielectric layer 109a may be formed using any suitable method, such as a spin-on coating process, a deposition process, and/or the like. In some embodiments, the patterned conductive layer 109b may be formed of conductive material, e.g., copper, titanium, tungsten, aluminum, metal alloy, a combination of these, or the like). The numbers of the dielectric layer 109a and the patterned conductive layer 109b may be selected based on demand and are not limited in the disclosure. In some embodiments, the redistribution structure 109 can be interchangeably referred to as a redistribution layer.

Reference is made to FIG. 5K. A heat sink 110 is formed over the redistribution structure 109 so as to reduce the junction temperature of the redistribution structure 109. As a result, the heat sink 110 may help to dissipate the heat generated from the redistribution structure 109. The heat sink 110 may be formed of a conductive material such as copper, silver, gold, tungsten, aluminum, combinations thereof or the like. A variety of deposition methods such as Physical Vapor Deposition (PVD) by sputtering, evaporation, PECVD and electroplating can be used to form the heat sink 110. Subsequently, the carrier wafer 100, the adhesive material 101, and the bonding pad 105 can removed from the BEOL structure 102, as shown in FIG. 5M.

Reference is made to FIGS. 5J, 5L, 5N, and 5O-5T. FIGS. 5J, 5L, and 5N illustrate schematic cross-sectional views of a semiconductor structure corresponding to FIGS. 5I, 5K, and 5M, respectively, according to some embodiments of the present disclosure. FIGS. 5O-5T illustrate schematic cross-sectional views of different semiconductor structures corresponding to FIG. 5I according to some embodiments of the present disclosure. While FIGS. 5J, 5L, 5N, and 5O-5T show embodiments of semiconductor structures with different thermal dissipation paths than the semiconductor structure in FIGS. 5A-51, 5K, and 5M. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 5J, 5L, and 5N, the difference between the embodiment in FIGS. 4K, 4M, and 4O and the embodiment in FIGS. 4A-4L, 4N, and 4P is in that an additional dielectric layer 114c is formed over the back-side 104b of the substrate 104 and in a same level height as the patterned conductive layer of the redistribution structure 109. The TSV 119a is in contact with the dielectric layer 114c, such that the TSV 119a and the dielectric layer 114c can be served as a thermal dissipation path that connects metal layers on wafer front-side and wafer back-side. In some embodiments, the dielectric layer 114c may be made of a dielectric material may have a thermal conductivity greater than about 150 W/m/K (kₜₕ). In some embodiments, the dielectric layer 214c may include metal oxide (e.g., beryllium oxide (BeO)) or metal nitride (e.g., aluminum nitride (AlN)). In some embodiments, the dielectric layer 114c may include chemical vapor deposition (CVD) diamond. In some embodiments, the dielectric layer 114c is formed by a deposition process including a chemical vapor deposition (CVD) process, such as high density plasma CVD (HDP-CVD), flowable chemical vapor deposition (FCVD), the like, or a combination thereof. Other suitable materials formed by any acceptable process may be used to form the dielectric layer 114c. In some embodiments, the dielectric layer 114c is metal-free. For example, the dielectric layer 114c can be made of metal oxide (e.g., beryllium oxide (BeO)), metal nitride (e.g., aluminum nitride (AlN)), a combination thereof, or other suitable materials. In some embodiments, the dielectric layer 114c may be made of a same material as the TSV 119a. In some embodiments, the dielectric layer 114c may be made of a different material than the TSV 119a. In some embodiments, the dielectric layer 114c can be interchangeably referred to as a dielectric lateral structure.

As shown in FIGS. 5O and 5P, the difference between the embodiments in FIGS. 5O and 5P and the embodiment in FIGS. 4A-4L, 4N, and 4P is in that TSV 119b (see FIG. 40)/TSV 119c (see FIG. 4P) further extends to an outermost surface 102f the BEOL structure 102, such that the TSV 119b/TSV 119c can be served as a thermal dissipation path that connects metal layers on wafer front-side and wafer back-side. In addition, the semiconductor shown in FIG. 4P has an additional dielectric layer 114d formed over the back-side 104b of the substrate 104 and in a same level height as the patterned conductive layer of the redistribution structure 109 than the semiconductor shown in FIGS. 5A-51, 5K, and 5M. Material and manufacturing method for forming the TSV 119b/TSV 119c and dielectric layer 114d are substantially the same as the material and manufacturing method for forming the TSV 119a and dielectric layer 114c described in foregoing descriptions and thus is not repeated herein for the sake of clarity.

As shown in FIGS. 5Q and 5R, the difference between the embodiments in FIGS. 5Q and 5R and the embodiment in FIGS. 4A-4L, 4N, and 4P is in that a substrate 154, a FEOL structure 153, and a BEOL structure 152 can be formed over the BEOL structure 102 in sequence prior to the formation of the TSV 119a, such that the TSV 119a can be served as a thermal dissipation path that connects metal layers on the wafer back-side wafer and the wafer front-side further including the substrate 154, the FEOL structure 153, and the BEOL structure 152. Material and manufacturing method for forming the substrate 154, the BEOL structure 152 and FEOL structure 153 are substantially the same as the material and manufacturing method for forming substrate 104, the BEOL structure 102 and FEOL structure 103 described in foregoing descriptions and thus are not repeated herein for the sake of clarity.

As shown in FIGS. 5S and 5T, the difference between the embodiments in FIGS. 5S and 5T and the embodiment in FIGS. 4A-4L, 4N, and 4P is in that a substrate 164, a FEOL structure 163, and a BEOL structure 162 can be formed over the BEOL structure 102 in sequence prior to the formation of the TSV 119d, and the TSV 119d/the TSV 119e further extends to an outermost surface 162f the BEOL structure 162, such that the TSV 119d can be served as a thermal dissipation path that connects metal layers on the wafer back-side wafer and the wafer front-side further including the substrate 164, the FEOL structure 163, and the BEOL structure 162. Material and manufacturing method for forming the TSV 119d/the TSV 119e, the substrate 164, the BEOL structure 162 and FEOL structure 163 are substantially the same as the material and manufacturing method for forming the TSV 119a, the substrate 104, the BEOL structure 102 and FEOL structure 103 described in foregoing descriptions and thus are not repeated herein for the sake of clarity.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a TSV that is made of a dielectric material having a higher thermal conductivity than the substrate to improve heat dissipation of the IC structure. The TSV can be metal-free. The dielectric TSV may be used to act as a heat sink for the IC structure to discharge the heat generated by the semiconductor device from a circuit local hotspot to outside of the IC structure. In some embodiments, the thermal conductivity of the dielectric TSV may be greater than about 150 W/m/K (kₜₕ). Because the dielectric TSV can be metal-free, no parasitic capacitance will be generated in the IC structure around the dielectric TSV, which in turn prevents an additional leakage path in the IC structure, and thus the performance of the IC structure can be improved.

In some embodiments, a method includes forming a semiconductor device over a front-side of a substrate, the semiconductor device comprising a channel region, a gate structure across the channel region, and source/drain regions on the channel region and at opposite sides of the gate structure; forming a first source/drain contact on a first one of the source/drain regions; forming a front-side interconnect structure over the first source/drain contact; forming a first dielectric through-silicon via extending through the substrate from a cross-sectional view, the first dielectric through-silicon via overlapping the first source/drain contact from a top view; forming a back-side interconnect structure over a back-side of the substrate, wherein the first dielectric through-silicon via has a back-side surface in contact with the back-side interconnect structure. In some embodiments, the first dielectric through-silicon via is made of a material having a thermal conductivity greater than about 150 W/m/K. In some embodiments, the first dielectric through-silicon via is made of metal oxide. In some embodiments, the first dielectric through-silicon via is made of metal nitride. In some embodiments, the first dielectric through-silicon via has a front-side surface in contact with the first source/drain contact. In some embodiments, the method further includes forming a second source/drain contact on a second one of the source/drain regions; forming a second dielectric through-silicon via extending through the substrate, the second dielectric through-silicon via having a front-side surface in contact with the second source/drain contact. In some embodiments, the back-side interconnect structure comprises a dielectric layer and a metal line laterally extending in the dielectric layer, and the back-side surface of the first dielectric through-silicon via is in contact with the metal line. In some embodiments, the back-side interconnect structure comprises a dielectric layer, a metal line laterally extending in the dielectric layer, and a dielectric lateral structure in the dielectric layer, and the back-side surface of the first dielectric through-silicon via is in contact with the dielectric lateral structure. In some embodiments, the dielectric lateral structure is made of a same material as the first dielectric through-silicon via. In some embodiments, the method further includes forming a buried power rail on the front-side of the substrate; forming a metal through-silicon via extending through the substrate, the metal through-silicon via having a front-side surface in contact with the buried power rail, and a back-side surface in contact with the metal line of the back-side interconnect structure.

In some embodiments, a method includes forming an interconnect structure over a front-side of a substrate; etching the substrate from a back-side of the substrate to form a through-silicon via opening until the interconnect structure is exposed; forming a metal-free through-silicon via in the through-silicon via opening; forming a redistribution layer over the back-side of the substrate. In some embodiments, the metal-free through-silicon via is made of beryllium oxide, aluminum nitride, chemical vapor deposition diamond, or combinations thereof. In some embodiments, the redistribution layer comprises a dielectric layer and a metal line laterally extending in the dielectric layer, and the metal-free through-silicon via is in contact with the metal line. In some embodiments, the redistribution layer comprises a dielectric layer and a dielectric lateral structure in the dielectric layer, and the metal-free through-silicon via is in contact with the dielectric lateral structure. In some embodiments, the dielectric lateral structure is made of a same material as the metal-free through-silicon via.

In some embodiments, the semiconductor structure includes a first semiconductor substrate, a first interconnect structure, a second interconnect structure, a metal-containing through-silicon via (TSV), and a dielectric TSV. The first interconnect structure is over a front-side of the first semiconductor substrate. The second interconnect structure is over a back-side of the first semiconductor substrate. The metal-containing TSV extends though the first semiconductor substrate and is electrically coupled to the first and second interconnect structures. The dielectric TSV extends though the first semiconductor substrate. The dielectric TSV is made of a material having a thermal conductivity greater than about 150 W/m/K. In some embodiments, the semiconductor structure further includes a semiconductor device and a source/drain contact. The semiconductor device is on the front-side of the first semiconductor substrate. The semiconductor device includes a channel region, a gate structure extending across the channel region, and source/drain regions on the channel region and at opposite sides of the gate structure. The source/drain contact is on one of the source/drain regions. The dielectric TSV has a front-side surface in contact with the source/drain contact. In some embodiments, the second interconnect structure comprises a dielectric layer and a metal line laterally extending in the dielectric layer, and the dielectric TSV has a back-side surface in contact with the metal line. In some embodiments, the semiconductor structure further includes a second semiconductor substrate over a back-side surface of the second interconnect structure, and the dielectric TSV further downwardly extends though the second interconnect structure and the second semiconductor substrate. In some embodiments, the semiconductor structure further includes a redistribution layer over a back-side surface of the second semiconductor substrate, in which the dielectric TSV further extends to the redistribution layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor device over a front-side of a substrate, the semiconductor device comprising a channel region, a gate structure across the channel region, and source/drain regions on the channel region and at opposite sides of the gate structure;
forming a first source/drain contact on a first one of the source/drain regions;
forming a front-side interconnect structure over the first source/drain contact;
forming a first dielectric through-silicon via extending through the substrate from a cross-sectional view, the first dielectric through-silicon via overlapping the first source/drain contact from a top view; and
forming a back-side interconnect structure over a back-side of the substrate, wherein the first dielectric through-silicon via has a back-side surface in contact with the back-side interconnect structure.

2. The method of claim 1, wherein the first dielectric through-silicon via is made of a material having a thermal conductivity greater than about 150 W/m/K.

3. The method of claim 1, wherein the first dielectric through-silicon via is made of metal oxide.

4. The method of claim 1, wherein the first dielectric through-silicon via is made of metal nitride.

5. The method of claim 1, wherein the first dielectric through-silicon via has a front-side surface in contact with the first source/drain contact.

6. The method of claim 5, further comprising:
forming a second source/drain contact on a second one of the source/drain regions; and
forming a second dielectric through-silicon via extending through the substrate, the second dielectric through-silicon via having a front-side surface in contact with the second source/drain contact.

7. The method of claim 1, wherein the back-side interconnect structure comprises a dielectric layer and a metal line laterally extending in the dielectric layer, and the back-side surface of the first dielectric through-silicon via is in contact with the metal line.

8. The method of claim 1, wherein the back-side interconnect structure comprises a dielectric layer, a metal line laterally extending in the dielectric layer, and a dielectric lateral structure in the dielectric layer, and the back-side surface of the first dielectric through-silicon via is in contact with the dielectric lateral structure.

9. The method of claim 8, wherein the dielectric lateral structure is made of a same material as the first dielectric through-silicon via.

10. The method of claim 8, further comprising:
forming a buried power rail on the front-side of the substrate; and
forming a metal through-silicon via extending through the substrate, the metal through-silicon via having a front-side surface in contact with the buried power rail, and a back-side surface in contact with the metal line of the back-side interconnect structure.

11. A method, comprising:
forming an interconnect structure over a front-side of a substrate;
etching the substrate from a back-side of the substrate to form a through-silicon via opening until the interconnect structure is exposed;
forming a metal-free through-silicon via in the through-silicon via opening; and
forming a redistribution layer over the back-side of the substrate.

12. The method of claim 11, wherein the metal-free through-silicon via is made of beryllium oxide, aluminum nitride, chemical vapor deposition diamond, or combinations thereof.

13. The method of claim 11, wherein the redistribution layer comprises a dielectric layer and a metal line laterally extending in the dielectric layer, and the metal-free through-silicon via is in contact with the metal line.

14. The method of claim 11, wherein the redistribution layer comprises a dielectric layer and a dielectric lateral structure in the dielectric layer, and the metal-free through-silicon via is in contact with the dielectric lateral structure.

15. The method of claim 14, wherein the dielectric lateral structure is made of a same material as the metal-free through-silicon via.

16. A semiconductor structure, comprising:
a first semiconductor substrate;
a first interconnect structure over a front-side of the first semiconductor substrate;
a second interconnect structure over a back-side of the first semiconductor substrate;
a metal-containing through-silicon via (TSV) extending though the first semiconductor substrate and electrically coupled to the first and second interconnect structures; and
a dielectric TSV extending though the first semiconductor substrate, the dielectric TSV being made of a material having a thermal conductivity greater than about 150 W/m/K.

17. The semiconductor structure of claim 16, further comprising:
a semiconductor device on the front-side of the first semiconductor substrate, the semiconductor device comprising a channel region, a gate structure extending across the channel region, and source/drain regions on the channel region and at opposite sides of the gate structure; and
a source/drain contact on one of the source/drain regions, wherein the dielectric TSV has a front-side surface in contact with the source/drain contact.

18. The semiconductor structure of claim 16, wherein the second interconnect structure comprises a dielectric layer and a metal line laterally extending in the dielectric layer, and the dielectric TSV has a back-side surface in contact with the metal line.

19. The semiconductor structure of claim 16, further comprising:
a second semiconductor substrate over a back-side surface of the second interconnect structure, and the dielectric TSV further downwardly extends though the second interconnect structure and the second semiconductor substrate.

20. The semiconductor structure of claim 19, further comprising:
a redistribution layer over a back-side surface of the second semiconductor substrate, wherein the dielectric TSV further extends to the redistribution layer.
